(19) United States
(12) Patent Application Publication
(10) Pub. No.: US 2026/0007029 A1
(43) Pub. Date: Jan. 1, 2026

(54) DISPLAY PANEL, ELECTRONIC DEVICE INCLUDING THE SAME AND METHOD FOR MANUFACTURING THE DISPLAY PANEL

(71) Applicant: Samsung Display Co., Ltd., Yongin-Si (KR)

(72) Inventor: HOYOUNG SIM, Yongin-si (KR)

(21) Appl. No.: 19/184,172

(22) Filed: Apr. 21, 2025

(30) Foreign Application Priority Data
Jun. 26, 2024 (KR) 10-2024-0083766
Aug. 12, 2024 (KR) 10-2024-0107768

(51) Int. Cl. H10K 59/35; H10K 59/12; H10K 59/80

(52) U.S. Cl. CPC H10K 59/353; H10K 59/1201; H10K 59/873

(57) ABSTRACT

An embodiment of the inventive concept provides a display panel including a base layer, a pixel defining film disposed on the base layer and having an emission opening portion, a partition wall disposed on the pixel defining film and having a partition wall opening portion disposed in an area corresponding to the emission opening portion, a light emitting element including an anode, an emission pattern, and a cathode in contact with the partition wall, and disposed in the emission opening portion and the partition wall opening portion, and a lower inorganic encapsulation pattern which has a groove spaced apart from the partition wall and the light emitting element and covers the light emitting element, and the emission opening portion may have a shape symmetrical about at least two axes passing through a center of the emission opening portion in a plan view.

### CROSS-REFERENCE TO RELATED APPLICATIONS

This U.S. non-provisional patent application claims priority under 35 U.S.C. § 119 to Korean Patent Application Nos. 10-2024-0083766, filed on Jun. 26, 2024, and 10-2024-0107768, filed on Aug. 12, 2024, the entire contents of which are hereby incorporated by reference.

### BACKGROUND

The present disclosure herein relates to a display panel and an electronic device, and a method for manufacturing the same, and more particularly, to a display panel and an electronic device with improved display quality.

Electronic devices such as televisions, monitors, smartphones, and tablet computers, which provide images for users, include display panels that display the images. Various display panels such as liquid crystal display panels, organic light emitting display panels, electro wetting display panels, and electrophoretic display panels, are developed as the display panels.

An organic light emitting display panel may include an anode, a cathode, and an emission pattern. The emission pattern may be separated for each emission area, and the cathode may provide a common voltage to each emission area.

### SUMMARY

The present disclosure provides a display panel with improved display quality by forming a light emitting element without using a metal mask and a method for manufacturing the display panel.

An embodiment of the inventive concept provides a display panel including a base layer, a pixel defining film disposed on the base layer and having an emission opening portion, a partition wall disposed on the pixel defining film and having a partition wall opening portion disposed in an area corresponding to the emission opening portion, a light emitting element including an anode, an emission pattern, and a cathode in contact with the partition wall, and disposed in the emission opening portion and the partition wall opening portion, and a lower inorganic encapsulation pattern which has a groove spaced apart from the partition wall and the light emitting element and covers the light emitting element, and the emission opening portion may have a shape symmetrical about at least two axes passing through a center of the emission opening portion in a plan view.

In an embodiment, the light emitting element may include a first light emitting element, a second light emitting element, and a third light emitting element which emit light having different colors from each other, and the emission opening portion may include a first emission opening portion disposed in an area corresponding to the first light emitting element, a second emission opening portion disposed in an area corresponding to the second light emitting element, and a third emission opening portion disposed in an area corresponding to the third light emitting element.

In an embodiment, at least one of the first to third emission opening portions may have a circular shape in a plan view.

In an embodiment, at least one of the first to third emission opening portions may be symmetrical about all axes passing through a center of the at least one emission opening portion in a plan view.

In an embodiment, each of the first to third emission opening portions may have a circular shape in a plan view.

In an embodiment, at least one of the first to third emission opening portions may have a rectangular shape or a rhombic shape in a plan view.

In an embodiment, at least one of the first to third emission opening portions may have four inner side surfaces.

In an embodiment, each of the first to third emission opening portions may have a rectangular shape or a rhombic shape in a plan view.

In an embodiment, an end of the lower inorganic encapsulation pattern may surround an edge of the emission opening portion in a plan view.

In an embodiment, the lower inorganic encapsulation pattern may have a shape symmetrical about at least two axes passing through a center of the lower inorganic encapsulation pattern in a plan view.

In an embodiment, the lower inorganic encapsulation pattern may include a first lower inorganic encapsulation pattern which covers the first light emitting element and has a first groove spaced apart from the partition wall and the first light emitting element, a second lower inorganic encapsulation pattern which covers the second light emitting element and has a second groove spaced apart from the partition wall and the second light emitting element, and a third lower inorganic encapsulation pattern which covers the third light emitting element and has a third groove spaced apart from the partition wall and the third light emitting element.

In an embodiment, at least one of the first to third lower inorganic encapsulation patterns may be symmetrical about all axes passing through a center of the at least one lower inorganic encapsulation pattern in a plan view.

In an embodiment, each of the first to third lower inorganic encapsulation patterns may have a circular shape in a plan view.

In an embodiment, at least one of the first to third lower inorganic encapsulation patterns may have a rectangular shape or a rhombic shape in a plan view.

In an embodiment, each of the first to third lower inorganic encapsulation patterns may have a rectangular shape or a rhombic shape in a plan view.

In an embodiment of the inventive concept, a method for manufacturing a display panel includes providing a preliminary display panel including a base layer, a pixel defining film disposed on the base layer, and a preliminary partition wall disposed on the pixel defining film, patterning a first photoresist layer by using a first mask to form a first photoresist pattern, the first mask including a first transmission part and a first light blocking part which surrounds the first transmission part in a plan view, etching the preliminary partition wall to form a partition wall having an undercut using the first photoresist pattern as a mask, etching the pixel defining film to form an emission opening portion corresponding to a shape of the first transmission part using the first photoresist pattern as a mask, and forming a light emitting element in the emission opening portion and the partition wall opening portion, the light emitting element including an anode, an emission pattern, and a cathode. The first transmission part may have a shape symmetrical about at least two axes passing through a center of the first transmission part.

In an embodiment, the method for manufacturing the display panel may further include depositing a lower inorganic encapsulation layer which covers the partition wall and the light emitting element, patterning a second photoresist layer by using a second mask to form a second photoresist pattern, the second mask including a second light blocking part and a second transmission part which surrounds the second light blocking part in a plan view, and etching the lower inorganic encapsulation layer by using the second photoresist pattern to form a lower inorganic encapsulation pattern in an area corresponding to the second light blocking part. The second light blocking part may have a shape symmetrical about at least two axes passing through a center of the second light blocking part.

In an embodiment, the depositing of the lower inorganic encapsulation layer which covers the partition wall and the light emitting element may include forming a groove spaced apart from the partition wall and the light emitting element.

In an embodiment, the etching of the lower inorganic encapsulation layer to form the lower inorganic encapsulation pattern may include forming the lower inorganic encapsulation pattern having a circular shape, a rectangular shape, or a rhombic shape in a plan view.

In an embodiment, the forming of the emission opening portion in the pixel defining film may include forming the emission opening portion having a circular shape, a rectangular shape, or a rhombic shape in a plan view.

An embodiment of the inventive concept provides an electronic device providing an image and including a window, a display panel disposed below the window and a housing disposed below the display panel and coupled with the window to accommodate the display panel. The display panel include a base layer, a pixel defining film disposed on the base layer and having an emission opening portion, a partition wall disposed on the pixel defining film and having a partition wall opening portion disposed in an area corresponding to the emission opening portion, a light emitting element including an anode, an emission pattern, and a cathode in contact with the partition wall, and disposed in the emission opening portion and the partition wall opening portion, and a lower inorganic encapsulation pattern which has a groove spaced apart from the partition wall and the light emitting element and covers the light emitting element, and the emission opening portion may have a shape symmetrical about at least two axes passing through a center of the emission opening portion in a plan view.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1A is a perspective view of an electronic device according to an embodiment of the inventive concept;

FIG. 1B is an exploded perspective view of an electronic device according to an embodiment of the inventive concept;

FIG. 2 is a cross-sectional view of a display module according to an embodiment of the inventive concept;

FIG. 3 is a plan view of a display panel according to an embodiment of the inventive concept;

FIG. 4 is an enlarged plan view of a portion of a display area of a display panel according to an embodiment of the inventive concept;

FIG. 5 is a cross-sectional view of a display panel taken along line I-I′ in FIG. 3;

FIG. 6 is a cross-sectional view taken along cutting line II-II′ in FIG. 4;

FIG. 7 is a plan view of a portion of a display area of a display panel according to an embodiment of the inventive concept;

FIG. 8 is a plan view of a portion of a display area of a display panel according to an embodiment of the inventive concept;

FIGS. 9 and 10A are cross-sectional views illustrating some of steps of a method for manufacturing a display panel according to an embodiment of the inventive concept;

FIG. 10B is a plan view of a mask according to an embodiment of the inventive concept;

FIGS. 11, 12, 13, 14 and 15A are cross-sectional views illustrating some of steps of a method for manufacturing a display panel according to an embodiment of the inventive concept;

FIG. 15B is a plan view of a mask according to an embodiment of the inventive concept; and

FIGS. 16 and 17 are cross-sectional views illustrating some of steps of a method for manufacturing a display panel according to an embodiment of the inventive concept.

### DETAILED DESCRIPTION

In the present disclosure, it will be understood that when an element (or region, layer, section, etc.) is referred to as being “on”, “connected to” or “coupled to” another element, it can be directly on, connected or coupled to the other element or a third element may be disposed between the elements.

Like reference numbers or symbols refer to like elements throughout. In addition, in the drawings, the thickness, the ratio, and the dimension of elements are exaggerated for effective description of the technical contents. The term “and/or” includes one or more combinations which may be defined by relevant elements.

It will be understood that, although the terms first, second, etc. may be used herein to describe various elements, these elements should not be limited by these terms. These terms are only used to distinguish one element from another element. For example, a first element could be termed a second element without departing from the teachings of the present inventive concept, and similarly, a second element could be termed a first element. As used herein, the singular forms are intended to include the plural forms as well, unless the context clearly indicates otherwise.

In addition, the terms, such as “below”, “beneath”, “on” and “above”, are used for explaining the relation of elements shown in the drawings. The terms are relative concept and are explained based on the direction shown in the drawing.

It will be further understood that the terms such as “includes” or “has”, when used herein, specify the presence of stated features, numerals, steps, operations, elements, parts, or the combination thereof, but do not preclude the presence or addition of one or more other features, numerals, steps, operations, elements, parts, or the combination thereof.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the inventive concept will be described with reference to the accompanying drawings.

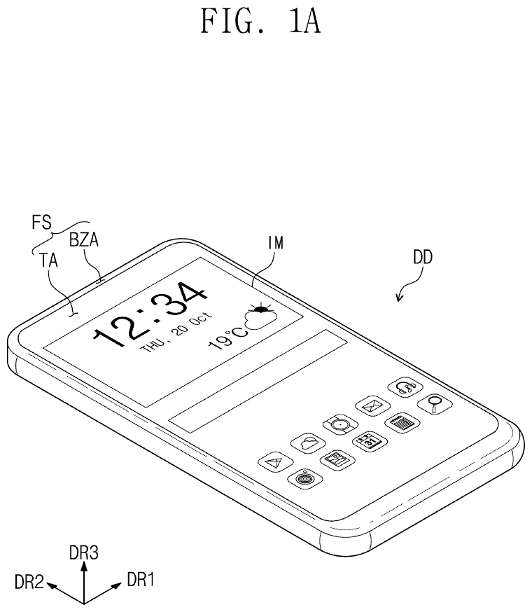

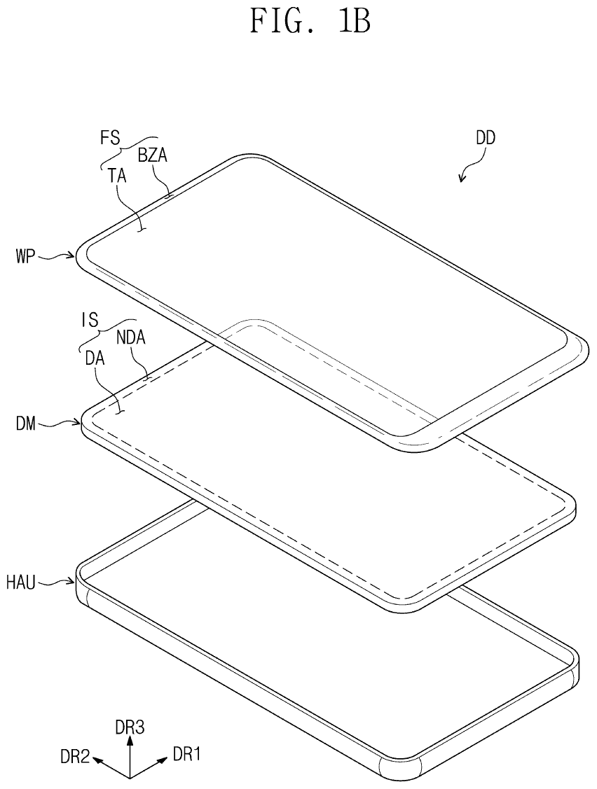

FIG. 1A is a perspective view of an electronic device DD according to an embodiment of the inventive concept. FIG. 1B is an exploded perspective view of the electronic device DD according to an embodiment of the inventive concept.

In an embodiment, the electronic device DD may be a large-sized electronic device such as a television, a monitor, or an outdoor billboard. Alternatively, the electronic device DD may be a small- and medium-sized electronic device such as a personal computer, a notebook computer, a personal digital assistant, a vehicle navigation unit, a game console, a smartphone, a tablet computer, and a camera. However, the foregoing devices are examples, and the electronic device DD may also be employed as another electronic device unless departing from the inventive concept. In FIGS. 1A and 1B, a smartphone is illustrated as an example of the electronic device DD.

Referring to FIGS. 1A and 1B, the electronic device DD may display an image IM in a third direction DR3 on a display surface FS extending parallel to each of a first direction DR1 and a second direction DR2. The image IM may include not only a dynamic image but also a still image. In FIG. 1A, a clock window and icons are illustrated as one example of the image IM. The display surface FS on which the image IM is displayed may correspond to a front surface of the electronic device DD.

In this embodiment, a front surface (or top surface) and a rear surface (or bottom surface) of each member are defined based on a direction in which the image IM is displayed. The front surface and the rear surface may oppose each other in the third direction DR3, and a normal direction to each of the front surface and the rear surface may be parallel to the third direction DR3. Meanwhile, directions indicated by the first to third directions DR1, DR2 and DR3 are relative concepts and may be changed to other directions. The term “in a plan view” used herein may mean being in a state when viewed in the third direction DR3.

The electronic device DD may include a window WP, a display module DM, and a housing HAU. The window WP and the housing HAU may be coupled to each other to constitute an outer appearance of the electronic device DD.

The window WP may include an optically transparent insulating material. For example, the window WP may include glass or plastic. The front surface of the window WP may define the display surface FS of the electronic device DD. The display surface FS may include a transmission area TA and a bezel area BZA. The transmission area TA may be an optically transparent area. For example, the transmission area TA may be an area having a visible light transmittance of about 90% or more.

The bezel area BZA may be an area having a relatively low light transmittance compared to the transmission area TA. The bezel area BZA may define a shape of the transmission area TA. The bezel area BZA may be disposed adjacent to the transmission area TA and surround the transmission area TA. However, this is illustrated as an example, and the bezel area BZA of the window WP may be omitted. The window WP may include at least one functional layer among an anti-fingerprint layer, a hard coating layer, and an anti-reflective layer, and is not limited to any one embodiment.

The display module DM may be disposed below the window WP. The display module DM may be a component that substantially generates the image IM. The image IM generated by the display module DM is displayed on a display surface IS of the display module DM and is externally visible to a user through the transmission area TA.

The display module DM may include a display area DA and a non-display area NDA. The display area DA may be an area that is activated in response to an electrical signal. The non-display area NDA may be disposed adjacent to the display area DA. The non-display area NDA may surround the display area DA. The non-display area NDA may be an area covered by the bezel area BZA, and may not be visible from the outside.

The housing HAU may be coupled to the window WP. The housing HAU may be coupled to the window WP to provide a predetermined inner space. The display module DM may be accommodated in the inner space.

The housing HAU may include a material having relatively high rigidity. For example, the housing HAU may include a plurality of frames and/or plates, each of which includes glass, plastic or metal or is made of a combination thereof. The housing HAU may stably protect components of the electronic device DD accommodated in the inner space from external impact.

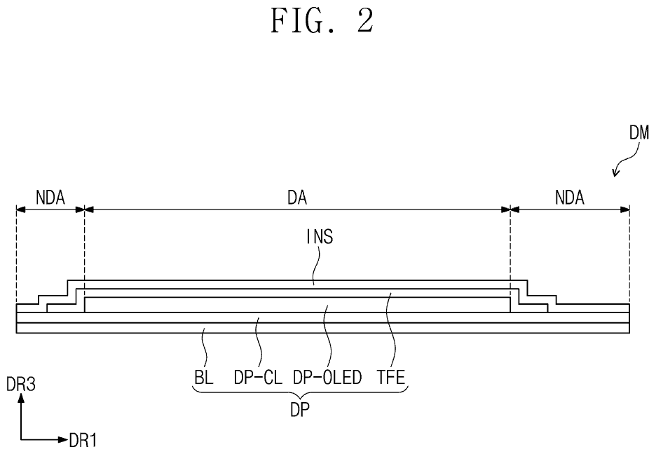

FIG. 2 is a cross-sectional view of a display module DM according to an embodiment of the inventive concept.

Referring to FIG. 2, the display module DM may include a display panel DP and an input sensor INS. Although not separately illustrated, the electronic device DD (see FIG. 1A) according to an embodiment of the inventive concept may further include a protective member disposed on a bottom surface of the display panel DP, or an anti-reflective member and/or a window member that are disposed on a top surface of the input sensor INS.

The display panel DP may be an emissive display panel. However, this is illustrative, and an embodiment of the inventive concept is not particularly limited thereto. For example, the display panel DP may be an organic light emitting display panel or an inorganic light emitting display panel. A light emitting layer in the organic light emitting display panel may include an organic light emitting material. A light emitting layer in the inorganic light emitting display panel may include a quantum dot, a quantum rod, or a micro LED. Hereinafter, the display panel DP is described as the organic light emitting display panel.

The display panel DP may include a base layer BL, and a circuit element layer DP-CL, a display element layer DP-OLED, and a thin-film encapsulation layer TFE that are disposed on the base layer BL. The input sensor INS may be directly disposed on the thin-film encapsulation layer TFE. In the present disclosure, when “a component A is directly disposed on a component B”, it means that an adhesive layer is not disposed between the component A and the component B.

The base layer BL may include at least one plastic film. The base layer BL may be a flexible substrate and include a plastic substrate, a glass substrate, a metal substrate, an organic/inorganic composite material substrate, or the like. A display area DA and a non-display area NDA the same as/similar to those described with reference to FIG. 1B may be defined in the base layer BL.

The circuit element layer DP-CL may include at least one insulating layer and a circuit element. The insulating layer includes at least one inorganic layer and at least one organic layer. The circuit element includes signal lines, a driving circuit of a pixel, and the like.

The display element layer DP-OLED may include a partition wall and a light emitting element. The light emitting element may include an anode, an intermediate layer, and a cathode.

The thin-film encapsulation layer TFE may include a plurality of thin films. Some of the thin films may be disposed to improve optical efficiency, and some of the thin films may be disposed to protect organic light emitting diodes.

The input sensor INS obtains coordinate information of an external input. The input sensor INS may have a multilayer structure. The input sensor INS may include a conductive layer having a single-layer or multilayer structure. In addition, the input sensor INS may include an insulating layer having a single-layer or multilayer structure. The input sensor INS may detect an external input by using a capacitance method. However, this is illustrative, and an embodiment of the inventive concept is not limited thereto. For example, in an embodiment, the input sensor INS may detect an external input by using an electromagnetic induction method or a pressure detection method. Alternatively, the input sensor INS may be omitted in an embodiment of the inventive concept.

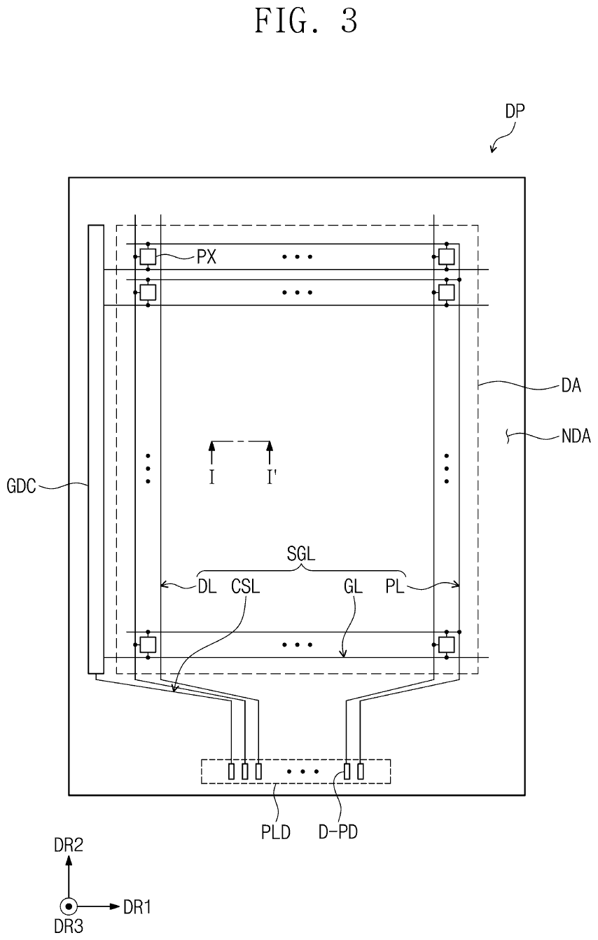

FIG. 3 is a plan view of a display panel according to an embodiment of the inventive concept.

Referring to FIG. 3, a display area DA, and a non-display area NDA around the display area DA may be defined in a display panel DP. The display panel DP may include pixels PX and signal lines SGL electrically connected to the pixels PX. The display panel DP may include a driving circuit GDC and a pad part PLD. The display area DA and the non-display area NDA may be classified according to whether the pixels PX are disposed or not. The pixels PX may be disposed in the display area DA. The driving circuit GDC and the pad part PLD may be disposed in the non-display area NDA.

The pixels PX may be arranged in the first direction DR1 and the second direction DR2. The pixels PX may include a plurality of pixel rows extending in the first direction DR1 and arranged in the second direction DR2, and a plurality of pixel columns extending in the second direction DR2 and arranged in the first direction DR1.

The signal lines SGL may include gate lines GL, data lines DL, a power line PL, and a control signal line CSL. Each of the gate lines GL may be connected to a corresponding pixels PX of the pixels PX, and each of the data lines DL may be connected to a corresponding pixels PX of the pixels PX. The power line PL may be electrically connected to the pixels PX. The control signal line CSL may be connected to the driving circuit GDC to provide control signals to the driving circuit GDC.

The driving circuit GDC may include a gate driving circuit. The gate driving circuit may generate gate signals and sequentially output the generated gate signals to the gate lines GL. The gate driving circuit may further output another control signal to a pixel driving circuit.

The pad part PLD may be a portion to which a flexible circuit board is connected. The pad part PLD may include pixel pads D-PD and the pixel pads D-PD may be pads for connecting the flexible circuit board to the display panel DP. Each of the pixel pads D-PD may be connected to a corresponding signal line of the signal lines SGL. The pixel pads D-PD may be connected to corresponding pixels PX through the signal lines SGL, respectively. In addition, one pixel pad of the pixel pads D-PD may be connected to the driving circuit GDC.

The pad part PLD may further include input pads. The input pads may be pads for connecting the flexible circuit board to the input sensor INS (see FIG. 2). However, an embodiment of the inventive concept is not limited thereto, and the input pads may be disposed in the input sensor INS (see FIG. 2) and connected to a separate circuit board from the pixel pads D-PD. Alternatively, the input sensor INS (see FIG. 2) may be omitted, and the input pads may not be further included.

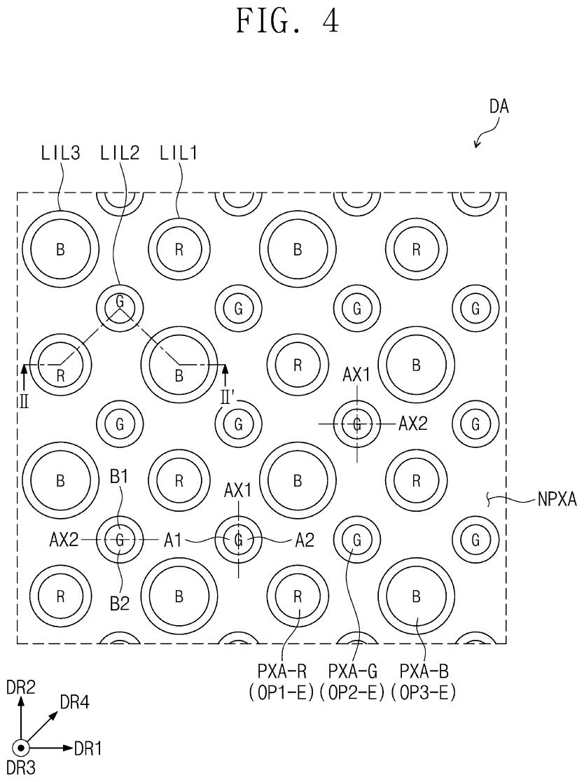

FIG. 4 is an enlarged plan view of a portion of a display area DA of the display panel DP (see FIG. 2) according to an embodiment of the inventive concept. FIG. 4 illustrates a plan view of the display module DM (see FIG. 1B) when viewed on the display surface IS (see FIG. 1B) of the display module DM, and illustrates an arrangement of emission areas PXA-R, PXA-G and PXA-B (or emission opening portions OP1-E, OP2-E and OP3-E) and lower inorganic encapsulation patterns LIL1, LIL2 and LIL3.

Referring to FIG. 4, the display area DA may include first to third emission areas PXA-R, PXA-G and PXA-B, and a peripheral area NPXA which surrounds the first to third emission areas PXA-R, PXA-G and PXA-B. The first to third emission areas PXA-R, PXA-G and PXA-B may be classified according to colors of light emitted toward the outside of the display module DM (see FIG. 2). The first to third emission areas PXA-R, PXA-G and PXA-B may correspond respectively to areas from which light provided from light emitting elements is emitted. The first to third emission areas PXA-R, PXA-G and PXA-B may correspond to the first to third emission opening portions OP1-E, OP2-E and OP3-E, respectively. For example, the first emission area PXA-R may correspond to the first emission opening portion OP1-E, the second emission area PXA-G may correspond to the second emission opening portion OP2-E, and the third emission area PXA-B may correspond to the third emission opening portion OP3-E.

The first to third emission areas PXA-R, PXA-G and PXA-B may provide light having first to third colors different from each other, respectively. For example, the light having the first color may be red light, the light having the second color may be green light, and the light having the third color may be blue light. However, examples of the light having the first to third colors are not necessarily limited to the foregoing examples.

Each of the first to third emission areas PXA-R, PXA-G and PXA-B may be defined as an area in which a top surface of an anode is not covered by a partition wall PW to be described later. The peripheral area NPXA may be a boundary between the first to third emission areas PXA-R, PXA-G and PXA-B, and prevent color mixture between the first to third emission areas PXA-R, PXA-G and PXA-B.

The first to third emission areas PXA-R, PXA-G and PXA-B may each be provided in plurality and be repeatedly disposed to have a predetermined arrangement shape in the display area DA. For example, the first and third emission areas PXA-R and PXA-B may be alternately arranged in the first direction DR1 to constitute a “first group”. The second emission areas PXA-G may be arranged in the first direction DR1 to constitute a “second group”. Each of the “first group” and the “second group” may be provided in plurality, and the “first groups” and the “second groups” may be alternately arranged in the second direction DR2.

One second emission area PXA-G may be disposed apart from one first emission area PXA-R or one third emission area PXA-B in a fourth direction DR4. The fourth direction DR4 may be defined as a direction between the first and second directions DR1 and DR2.

FIG. 4 illustrates an example of the arrangement shape of the first to third emission areas PXA-R, PXA-G and PXA-B. However, an embodiment of the inventive concept is not limited thereto and the first to third emission areas PXA-R, PXA-G and PXA-B may be arranged in various shapes. In an embodiment, the first to third emission areas PXA-R, PXA-G and PXA-B may have a PENTILE™ arrangement shape as illustrated in FIG. 4. Alternatively, the first to third emission areas PXA-R, PXA-G and PXA-B may have a stripe arrangement shape or a diamond (Diamond Pixel™) arrangement shape.

The first to third emission opening portions OP1-E, OP2-E and OP3-E may have various shapes in a plan view. Each of the first to third emission opening portions OP1-E, OP2-E and OP3-E may have a shape such as a polygonal shape or a circular shape. At least one of the first to third emission opening portions OP1-E, OP2-E and OP3-E may have a circular shape in a plan view.

Each of the first to third emission opening portions OP1-E, OP2-E and OP3-E may have a shape symmetrical about at least two axes passing through a center of the emission opening portion. For example, the second emission opening portion OP2-E may have a shape symmetrical about a first axis AX1 and a second axis AX2 each passing through the center of the second emission opening portion OP2-E. A (1-1)-th area A1 and a (1-2)-th area A2 of the second emission opening portion OP2-E, which are divided by the first axis AX1, may be symmetrical with each other. In addition, a (2-1)-th area B1 and a (2-2)-th area B2 of the second emission opening portion OP2-E, which are divided by the second axis AX2, may be symmetrical with each other.

In FIG. 4, the embodiment is described with an example of the two axes AX1 and AX2, but in a plan view, at least one of the first to third emission opening portions OP1-E, OP2-E and OP3-E may be symmetrical about all axes passing through the center of the at least one of the first to third emission opening portions OP1-E, OP2-E and OP3-E. In addition, in FIG. 4, the embodiment is described with an example of the second emission opening portion OP2-E, but the contents about the second emission opening portion OP2-E may apply to the first and third emission opening portions OP1-E and OP3-E.

The first to third emission areas PXA-R, PXA-G and PXA-B (or the first to third emission opening portions OP1-E, OP2-E and OP3-E) may have the same shape in a plan view, or alternatively, at least some thereof may have different shapes in a plan view. As an example, FIG. 4 illustrates the first to third emission opening portions OP1-E, OP2-E and OP3-E having the same circular shape in a plan view.

At least some of the first to third emission areas PXA-R, PXA-G and PXA-B may have different surface areas in a plan view. In an embodiment, a surface area of the first emission area PXA-R that emits the red light may be greater than a surface area of the second emission area PXA-G that emits the green light, and be less than a surface area of the third emission area PXA-B that emits the blue light. However, a large-small relationship between the surface areas of the first to third emission areas PXA-R, PXA-G and PXA-B according to the colors of the emitted light is not limited thereto, and may vary according to the design of the display module DM (see FIG. 2). Also, an embodiment of the inventive concept is not limited thereto and the first to third emission areas PXA-R, PXA-G and PXA-B may have the same surface area in a plan view.

The shape, surface area, arrangement, and the like of the first to third emission areas PXA-R, PXA-G and PXA-B of the display module DM (see FIG. 2) according to an embodiment of the inventive concept may be variously designed according to the colors of the emitted light or the size or configuration of the display module DM (see FIG. 2), and are not limited to the embodiment illustrated in FIG. 4.

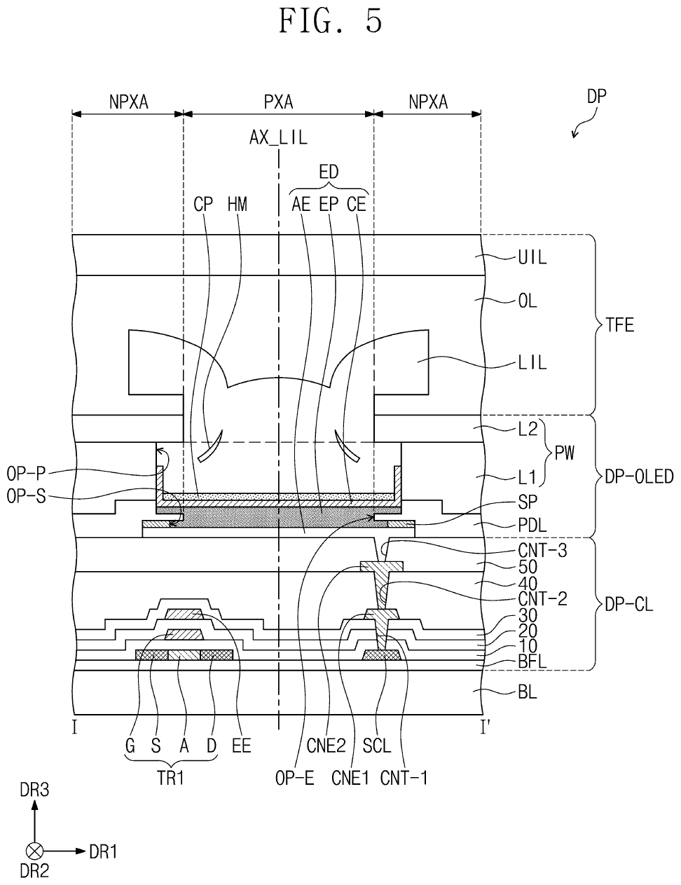

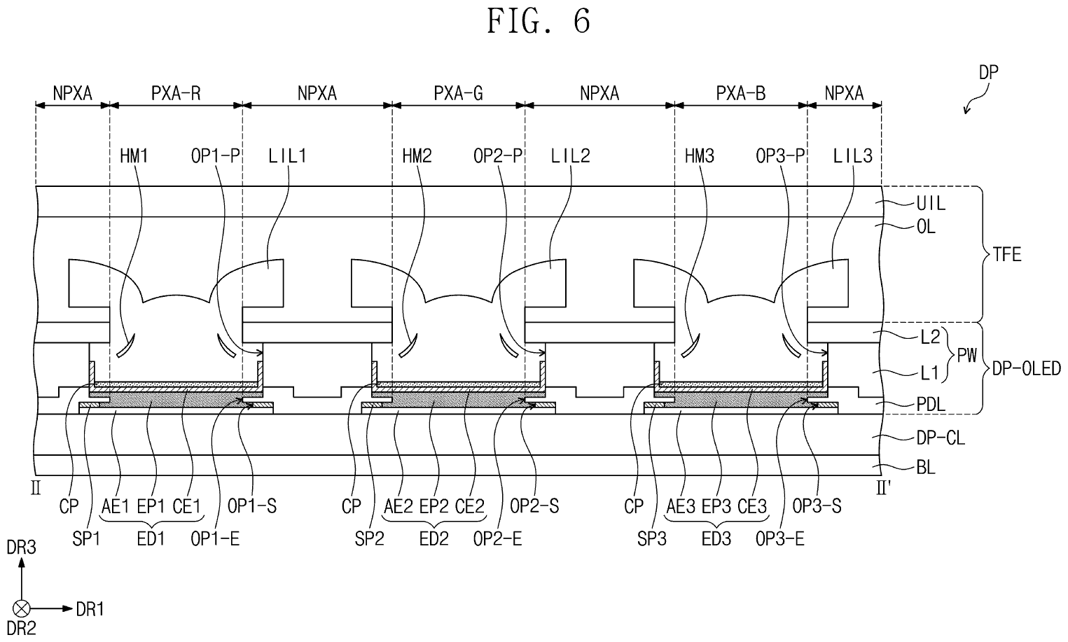

A lower inorganic encapsulation pattern LIL (see FIG. 5) may cover a light emitting element ED (see FIG. 5) to be described later. The lower inorganic encapsulation pattern LIL may be provided in plurality. The lower inorganic encapsulation patterns LIL1, LIL2 and LIL3 may include a first lower inorganic encapsulation pattern LIL1 which covers a first light emitting element ED1 (see FIG. 6), a second lower inorganic encapsulation pattern LIL2 which covers a second light emitting element ED2 (see FIG. 6), and a third lower inorganic encapsulation pattern LIL3 which covers a third light emitting element ED3 (see FIG. 6).

In a plan view, ends of the lower inorganic encapsulation patterns LIL1, LIL2 and LIL3 may surround the emission opening portions OP1-E, OP2-E and OP3-E, respectively. For example, the end of the first lower inorganic encapsulation pattern LIL1 may surround the first emission opening portion OP1-E, the end of the second lower inorganic encapsulation pattern LIL2 may surround the second emission opening portion OP2-E, and the end of the third lower inorganic encapsulation pattern LIL3 may surround the third emission opening portion OP3-E.

The first to third lower inorganic encapsulation patterns LIL1, LIL2 and LIL3 may have various shapes in a plan view. The shapes of the first to third lower inorganic encapsulation patterns LIL1, LIL2 and LIL3 may correspond to the shapes of the first to third emission opening portions OP1-E, OP2-E and OP3-E, respectively. Each of the first to third lower inorganic encapsulation patterns LIL1, LIL2 and LIL3 may have a shape such as a polygonal shape or a circular shape. At least one of the first to third lower inorganic encapsulation patterns LIL1, LIL2 and LIL3 may have a circular shape in a plan view. That is, in a plan view, at least one of the first to third lower inorganic encapsulation patterns LIL1, LIL2 and LIL3 may be symmetrical about all axes passing through a center of the at least one of the first to third lower inorganic encapsulation patterns LIL1, LIL2 and LIL3.

Each of the first to third lower inorganic encapsulation patterns LIL1, LIL2 and LIL3 may have a shape symmetrical about at least two axes passing through a center of the each of the first to third lower inorganic encapsulation patterns LIL1, LIL2 and LIL3. For example, the second lower inorganic encapsulation pattern LIL2 may have a shape symmetrical about the first axis AX1 and the second axis AX2 each passing through the center of the second lower inorganic encapsulation pattern LIL2. A (1-1)-th area and a (1-2)-th area of the second lower inorganic encapsulation pattern LIL2 (which correspond respectively to the (1-1)-th area A1 and the (1-2)-th area A2 of the second emission opening portion OP2-E), which are divided by the first axis AX1, may be symmetrical with each other. In addition, a (2-1)-th area and a (2-2)-th area of the second lower inorganic encapsulation pattern LIL2 (which correspond respectively to the (2-1)-th area B1 and the (2-2)-th area B2 of the second emission opening portion OP2-E), which are divided by the second axis AX2, may be symmetrical with each other.

In FIG. 4, the embodiment is described with an example of the two axes AX1 and AX2, but in a plan view, at least one of the first to third lower inorganic encapsulation patterns LIL1, LIL2 and LIL3 may be symmetrical about all axes passing through the center of the least one of the first to third lower inorganic encapsulation patterns LIL1, LIL2 and LIL3. In addition, in FIG. 4, the embodiment is described with an example of the second lower inorganic encapsulation pattern LIL2, but the contents about the second lower inorganic encapsulation pattern LIL2 may apply to the first and third lower inorganic encapsulation patterns LIL1 and LIL3.

The first to third lower inorganic encapsulation patterns LIL1, LIL2 and LIL3 may have the same shape in a plan view, or alternatively, at least some thereof may have different shapes in a plan view. As an example, FIG. 4 illustrates the first to third lower inorganic encapsulation patterns LIL1, LIL2 and LIL3 having the same circular shape in a plan view.

FIG. 5 is a cross-sectional view of a display panel taken along line I-I′ in FIG. 3. An embodiment in FIG. 5 will be described by referring to FIG. 2 and avoid repetitive explanation about components designated by like reference numbers or symbols. FIG. 5 illustrates an enlarged view of one emission area PXA in the display area DA (see FIG. 4), and the emission area PXA in FIG. 5 may correspond to any one of the first to third emission areas PXA-R, PXA-G and PXA-B in FIG. 4.

Referring to FIG. 5, a display panel DP may include a base layer BL, a circuit element layer DP-CL, a display element layer DP-OLED, and a thin-film encapsulation layer TFE.

The display panel DP may include a plurality of insulating layers, a semiconductor pattern, a conductive pattern, a signal line, and the like. The insulating layers, a semiconductor layer, and a conductive layer are formed using a method such as coating or deposition. Thereafter, the insulating layers, the semiconductor layer, and the conductive layer may be selectively patterned through a photolithography process and an etching process. The semiconductor pattern, the conductive pattern, and the signal line, and the like, which are included in the circuit element layer DP-CL and the display element layer DP-OLED, may be formed by that method.

The circuit element layer DP-CL may be disposed on the base layer BL. The circuit element layer DP-CL may include a buffer layer BFL, a transistor TR1, a signal transmission layer SCL, first to fifth insulating layers 10, 20, 30, 40 and 50, an electrode EE, and a plurality of connection electrodes CNE1 and CNE2.

The buffer layer BFL may be disposed on the base layer BL. The buffer layer BFL may improve bonding force between the base layer BL and the semiconductor pattern. The buffer layer BFL may include a silicon oxide layer and a silicon nitride layer. The silicon oxide layer and the silicon nitride layer may be alternately stacked.

The semiconductor pattern may be disposed on the buffer layer BFL. The semiconductor pattern may include polysilicon. However, an embodiment of the inventive concept is not limited thereto, and the semiconductor pattern may include amorphous silicon or a metal oxide. As an example, FIG. 5 just illustrates a portion of the semiconductor pattern, and the semiconductor pattern may be further disposed in the plurality of emission areas PXA-R, PXA-G and PXA-B (see FIG. 4). The semiconductor pattern may be arranged over the plurality of emission areas PXA-R, PXA-G and PXA-B (see FIG. 5) according to a specific rule. The semiconductor pattern may have different electrical properties according to whether the semiconductor pattern is doped or not. The semiconductor pattern may include a first region having a high doping concentration and a second region having a low doping concentration. The first region may be doped with an n-type dopant or a p-type dopant. A p-type transistor may include the first region doped with the p-type dopant.

The first region has higher conductivity than the second region, and substantially serves as an electrode or a signal line. The second region may substantially correspond to an active (or channel) of a transistor. In other words, a portion of the semiconductor pattern may be an active of a transistor, another portion may be a source or a drain of the transistor, and still another portion may be a conductive region.

A source S, an active A, and a drain D of the transistor TR1 may be provided from the semiconductor pattern. FIG. 5 illustrates a portion of the signal transmission layer SCL provided from the semiconductor pattern. Although not separately illustrated, the signal transmission layer SCL may be connected to the drain D of the transistor TR1 in a plan view.

The first to fifth insulating layers 10, 20, 30, 40 and 50 may be disposed on the buffer layer BFL. Each of the first to fifth insulating layers 10, 20, 30, 40 and 50 may be an inorganic layer or an organic layer.

The first insulating layer 10 may be disposed on the buffer layer BFL. The first insulating layer 10 may cover the source S, the active A, and the drain D of the transistor TR1, and the signal transmission layer SCL, which are disposed on buffer layer BFL. A gate G of the transistor TR1 may be disposed on the first insulating layer 10. The second insulating layer 20 may be disposed on the first insulating layer 10 and cover the gate G. The electrode EE may be disposed on the second insulating layer 20. The third insulating layer 30 may be disposed on the second insulating layer 20 and cover the electrode EE.

A first connection electrode CNE1 may be disposed on the third insulating layer 30. The first connection electrode CNE1 may be connected to the signal transmission layer SCL through a contact hole CNT-1 passing through the first to third insulating layers 10, 20 and 30. The fourth insulating layer 40 may be disposed on the third insulating layer 30 and cover the first connection electrode CNE1. The fourth insulating layer 40 may be an organic layer.

A second connection electrode CNE2 may be disposed on the fourth insulating layer 40. The second connection electrode CNE2 may be connected to the first connection electrode CNE1 through a contact hole CNT-2 passing through the fourth insulating layer 40. The fifth insulating layer 50 may be disposed on the fourth insulating layer 40 and cover the second connection electrode CNE2. The fifth insulating layer 50 may be an organic layer.

The display element layer DP-OLED may be disposed on the circuit element layer DP-CL. The display element layer DP-OLED may include a light emitting element ED, a sacrificial pattern SP, a pixel defining film PDL, and a partition wall PW.

The light emitting element ED may include an anode AE (or first electrode), an emission pattern EP, and a cathode CE (or second electrode). The light emitting element ED may be disposed in an emission opening portion OP-E and a partition wall opening portion OP-P that will be described later.

The anode AE may be disposed on the fifth insulating layer 50 of the circuit element layer DP-CL. The anode AE may be a transmissive electrode, a semi-transmissive electrode, or a reflective electrode. The anode AE may be connected to the second connection electrode CNE2 through a connection contact hole CNT-3 passing through and defined in the fifth insulating layer 50. Thus, the anode AE may be electrically connected to the signal transmission layer SCL through the first and second connection electrodes CNE1 and CNE2, and be electrically connected to a corresponding circuit element. The anode AE may have a single-layer structure or a multilayer structure. The anode AE may include a plurality of layers including ITO or Ag. For example, the anode AE may include a layer including ITO (hereinafter referred to as a lower ITO layer), a layer disposed on the lower ITO layer and including Ag (hereinafter referred to as an Ag layer), and a layer disposed on the Ag layer and including ITO (hereinafter referred to as an upper ITO layer).

The sacrificial pattern SP may be disposed between the anode AE and the pixel defining film PDL. A sacrificial opening portion OP-S which exposes a portion of a top surface of the anode AE during a manufacturing process may be defined (or provided) in the sacrificial pattern SP. The sacrificial opening portion OP-S may be an area corresponding to the emission opening portion OP-E to be described later.

The pixel defining film PDL may be disposed on the fifth insulating layer 50 of the circuit element layer DP-CL. The emission opening portion OP-E may be defined (or provided) in the pixel defining film PDL. The emission opening portion OP-E may be formed in an area corresponding to the anode AE, and the pixel defining film PDL may expose at least a portion of the anode AE through the emission opening portion OP-E during a manufacturing process.

In addition, the emission opening portion OP-E may be smaller than the sacrificial opening portion OP-S of the sacrificial pattern SP in a plan view. The pixel defining film PDL may cover edges of the sacrificial pattern SP in a plan view. According to this embodiment, the top surface of the anode AE may be spaced apart from the pixel defining film PDL with the sacrificial pattern SP disposed therebetween in a cross-sectional view, and, accordingly, the anode AE may be protected from damage in a process of forming the emission opening portion OP-E.

In a plan view, a surface area of the emission opening portion OP-E may be less than a surface area of the sacrificial opening portion OP-S. That is, an inner side surface of the pixel defining film PDL, which defines the emission opening portion OP-E, may protrude to a center of the anode AE than an inner side surface of the sacrificial pattern SP, which defines the sacrificial opening portion OP-S, is. However, an embodiment of the inventive concept is not limited thereto, and the inner side surface of the sacrificial pattern SP, which defines the sacrificial opening portion OP-S, may be substantially aligned with the inner side surface of the pixel defining film PDL, which defines the emission opening portion OP-E. Here, the emission area PXA may refer to an area of the anode AE not covered by the sacrificial pattern.

The pixel defining film PDL may include an inorganic insulating material. For example, the pixel defining film PDL may include a silicon nitride (SiNₓ). The pixel defining film PDL may be disposed between the anode AE and the partition wall PW to block an electrical connection between the anode AE and the partition wall PW.

The emission pattern EP may be disposed on the anode AE. The emission pattern EP may include a light emitting layer including a light emitting material. The emission pattern EP may further include a hole injection layer HIL and a hole transport layer HTL, which are disposed between the anode AE and the light emitting layer, and may further include an electron transport layer ETL and an electron injection layer EIL which are disposed on the light emitting layer. The emission pattern EP may be referred to as an “organic layer” or an “intermediate layer.”

The emission pattern EP may be patterned by a tip part defined in the partition wall PW. This will be described later in detail in a method for manufacturing a display panel. The emission pattern EP may be disposed inside the sacrificial opening portion OP-S and the emission opening portion OP-E. However, this is illustrated as an example, and the emission pattern EP may be disposed inside at least one of the sacrificial opening portion OP-S, the emission opening portion OP-E, or the partition wall opening portion OP-P. The emission pattern EP may cover a portion of a top surface of the pixel defining film PDL.

The cathode CE may be disposed on the emission pattern EP. The cathode CE may be patterned by the tip part defined in the partition wall PW. At least a portion of the cathode CE may be disposed in the partition wall opening portion OP-P. As an example, FIG. 5 illustrates the cathode CE disposed in the emission opening portion OP-E and the partition wall opening portion OP-P, but an embodiment of the inventive concept is not limited thereto. For example, the cathode CE may be disposed only in the partition wall opening portion OP-P.

The cathode CE may extend along a first inner side surface of a first partition wall layer L1, and an end of the cathode CE may be in contact with the first partition wall layer L1. As an example, FIG. 5 illustrates the cathode CE in contact with the first inner side surface of the first partition wall layer L1 and the inner side surface of the pixel defining film PDL, but an embodiment of the inventive concept is not limited thereto. For example, the cathode CE may be provided to be in contact with only the first inner side surface of the first partition wall layer L1.

The cathode CE may have conductivity. The cathode CE may be made of various materials such as a metal, a transparent conductive oxide (TCO), or a conductive polymer material, as long as being capable of having conductivity. For example, the cathode CE may include silver (Ag), magnesium (Mg), lead (Pb), copper (Cu), or a compound thereof.

In an embodiment of the inventive concept, the display element layer DP-OLED may further include a capping pattern CP. The capping pattern CP may be disposed in the partition wall opening portion OP-P and disposed on the cathode CE. The capping pattern CP may be patterned by the tip part defined in the partition wall PW. In an embodiment, the capping pattern CP may be omitted.

The partition wall PW may be disposed on the pixel defining film PDL. The partition wall opening portion OP-P may be defined in the partition wall PW. The partition wall opening portion OP-P may be an area corresponding to the emission opening portion OP-E in a plan view, and expose at least a portion of the anode AE during a manufacturing process.

The partition wall PW may include a plurality of layers that are stacked in sequence. For example, the partition wall PW may include the first partition wall layer L1 and a second partition wall layer L2. The first partition wall layer L1 may be disposed on the pixel defining film PDL, and the second partition wall layer L2 may be disposed on the first partition wall layer L1. As illustrated in FIG. 5, a thickness of the first partition wall layer L1 may be greater than a thickness of the second partition wall layer L2, but is not limited thereto.

Each of the first partition wall layer L1 and the second partition wall layer L2 may include a conductive material. For example, the conductive material may include a metal, a transparent conductive oxide (TCO), or a combination thereof. For example, the metal may include gold (Au), silver (Ag), aluminum (Al), magnesium (Mg), lithium (Li), molybdenum (Mo), titanium (Ti), copper (Cu), or an alloy. The transparent conductive oxide may include an indium tin oxide (ITO), an indium zinc oxide (IZO), a zinc oxide, an indium oxide, an indium gallium oxide, an indium gallium zinc oxide (IGZO), or an aluminum zinc oxide.

The partition wall PW may have an undercut shape in a cross-sectional view. At least one of the plurality of layers of the partition wall PW may be recessed from the other layers, and accordingly, the partition wall PW may include the tip part protruding toward a center of the anode AE. For example, the first partition wall layer L1 may have an undercut shape with respect to the second partition wall layer L2. The second partition wall layer L2 may protrude from the first partition wall layer L1 toward the emission opening portion OP-E and provide the tip part. A portion of the second partition wall layer L2 protruding from the first partition wall layer L1 toward the emission area PXA may be defined as the tip part in the partition wall PW. That is, a second inner side surface of the second partition wall layer L2 may be disposed closer to the center of the anode AE than the first inner side surface of the first partition wall layer L1 is.

As an example, FIG. 5 illustrates the first inner side surface of the first partition wall layer L1 and the second inner side surface of the second partition wall layer L2, each of which is perpendicular to the top surface of the pixel defining film PDL, but an embodiment of the inventive concept is not limited thereto. For example, the partition wall PW may have a tapered shape, or may have a reverse tapered shape.

The partition wall PW may receive a driving voltage, and accordingly, the cathode CE may be electrically connected to the partition wall PW and receive the driving voltage.

The thin-film encapsulation layer TFE may be disposed on the display element layer DP-OLED. The thin-film encapsulation layer TFE may include a lower inorganic encapsulation pattern LIL, an organic encapsulation film OL, and an upper inorganic encapsulation film UIL.

The lower inorganic encapsulation pattern LIL may be disposed in an area corresponding to the emission opening portion OP-E. The lower inorganic encapsulation pattern LIL may be disposed on the capping pattern CP and cover the light emitting element ED. A portion of the lower inorganic encapsulation pattern LIL may be provided in the partition wall opening portion OP-P, and another portion of the lower inorganic encapsulation pattern LIL may be provided on the partition wall PW.

A groove HM, where the lower inorganic encapsulation pattern LIL is absent due to bad step coverage, may be formed in the lower inorganic encapsulation pattern LIL. The groove HM of the lower inorganic encapsulation pattern LIL may be spaced apart from the partition wall PW and the light emitting element ED. The lower inorganic encapsulation pattern LIL may have a shape symmetrical about an axis AX_LIL passing through a center of the lower inorganic encapsulation pattern LIL.

The organic encapsulation film OL may be disposed on the lower inorganic encapsulation pattern LIL. The organic encapsulation film OL may cover the lower inorganic encapsulation pattern LIL and provide a flat top surface. The upper inorganic encapsulation film UIL may be disposed on the organic encapsulation film OL. The lower inorganic encapsulation pattern LIL and the upper inorganic encapsulation film UIL may protect the display element layer DP-OLED from moisture/oxygen, and the organic encapsulation film OL may protect the display element layer DP-OLED from foreign substances such as dust particles.

FIG. 6 is a cross-sectional view taken along cutting line II-II′ in FIG. 4. FIG. 6 illustrates an enlarged view of one first emission area PXA-R, one second emission area PXA-G, and one third emission area PXA-B, and the explanation about the one emission area PXA in FIG. 5 may apply to each of the first to third emission areas PXA-R, PXA-G and PXA-B in FIG. 6. An embodiment will be described with reference to FIG. 6 by denoting the same/similar components as/to those described with reference to FIG. 5 as the same/similar reference numbers or symbols, and avoiding redundant explanation.

Referring to FIG. 6, a display panel DP may include a base layer BL, a circuit element layer DP-CL, a display element layer DP-OLED, and a thin-film encapsulation layer TFE. The display element layer DP-OLED may include light emitting elements ED1, ED2 and ED3, sacrificial patterns SP1, SP2 and SP3, a pixel defining film PDL, and a partition wall PW.

The light emitting elements ED1, ED2 and ED3 may include a first light emitting element ED1, a second light emitting element ED2, and a third light emitting element ED3 which emit light having different colors from each other. Each of the first light emitting element ED1, the second light emitting element ED2, and the third light emitting element ED3 may be provided in plurality. Only for concise explanation, one of the plurality of the first light emitting elements ED1, one of the second light emitting elements ED2, and one of the third light emitting elements ED3 will be described.

The first light emitting element ED1 may include a first anode AE1, a first emission pattern EP1, and a first cathode CE1. The second light emitting element ED2 may include a second anode AE2, a second emission pattern EP2, and a second cathode CE2. The third light emitting element ED3 may include a third anode AE3, a third emission pattern EP3, and a third cathode CE3. The first to third anodes AE1, AE2 and AE3 may be provided as a plurality of patterns. In an embodiment, the first emission pattern EP1 may provide red light, the second emission pattern EP2 may provide green light, and the third emission pattern EP3 may provide blue light.

First to third emission opening portions OP1-E, OP2-E and OP3-E may be defined in the pixel defining film PDL. The first emission opening portion OP1-E may expose at least a portion of the first anode AE1 during a manufacturing process. The second emission opening portion OP2-E may expose at least a portion of the second anode AE2 during a manufacturing process. The third emission opening portion OP3-E may expose at least a portion of the third anode AE3 during a manufacturing process.

In this embodiment, the first emission area PXA-R may be defined as an area of the first anode AE1 which is not covered by the pixel defining film PDL. The second emission area PXA-G may be defined as an area of the second anode AE2 which is not covered by the pixel defining film PDL. The third emission area PXA-B may be defined as an area of the third anode AE3 which is not covered by the pixel defining film PDL.

The sacrificial patterns SP1, SP2 and SP3 may include a first sacrificial pattern SP1, a second sacrificial pattern SP2, and a third sacrificial pattern SP3. The first to third sacrificial patterns SP1, SP2 and SP3 may be disposed on the top surfaces of the first to third anodes AE1, AE2 and AE3, respectively. First to third sacrificial opening portions OP1-S, OP2-S and OP3-S disposed in areas corresponding to the first to third emission opening portions OP1-E, OP2-E and OP3-E may be defined in the first to third sacrificial patterns SP1, SP2 and SP3, respectively.

In this embodiment, first to third partition wall opening portions OP1-P, OP2-P and OP3-P disposed in areas corresponding to the first to third emission opening portions OP1-E, OP2-E and OP3-E, respectively, may be defined in the partition wall PW.

In this embodiment, the first to third emission patterns EP1, EP2 and EP3 and the first to third cathodes CE1, CE2 and CE3 may be physically separated due to a second partition wall layer L2, which includes a tip part and be defined in the emission opening portions OP1-E, OP2-E and OP3-E and the partition wall opening portions OP1-P, OP2-P and OP3-P. That is, the light emitting elements ED1, ED2 and ED3 may be disposed in the partition wall opening portions OP1-P, OP2-P and OP3-P and the emission opening portions OP1-E, OP2-E and OP3-E. For example, the first light emitting element ED1 may be disposed in the first partition wall opening portion OP1-P and the first emission opening portion OP1-E, the second light emitting element ED2 may be disposed in the second partition wall opening portion OP2-P and the second emission opening portion OP2-E, and the third light emitting element ED3 may be disposed in the third partition wall opening portion OP3-P and the third emission opening portion OP3-E.

According to an embodiment of the inventive concept, a plurality of first emission patterns EP1 may be patterned and deposited in pixel units due to the tip part defined on the partition wall PW. That is, the first emission patterns EP1 may be formed in common using an open mask, but may be disconnected to form isolated patterns due to the tip parts in the partition wall PW.

On the other hand, in a case in which a fine metal mask (FMM) is used to pattern the first emission patterns EP1, a support spacer protruding from a conductive partition wall needs to be provided to support the fine metal mask. In addition, as the fine metal mask is spaced a height of the partition wall and the spacer from a base surface on which the patterning is performed, achievement of high resolution may be restricted. Also, as the fine metal mask comes into contact with the spacer, foreign substances may remain on the spacer after the process of patterning the first emission patterns EP1, or the spacer may be damaged due to stabbing by the fine metal mask. As a result, a defective display panel may be provided.

According to this embodiment, as the partition wall PW is included, physical separation between the light emitting elements ED1, ED2 and ED3 may be easily achieved. Accordingly, driving errors or current leakage between adjacent emission areas PXA-R, PXA-G and PXA-B may be prevented, and the light emitting elements ED1, ED2 and ED3 may be driven independently of each other.

Particularly, the plurality of first emission patterns EP1 may be patterned without a mask in contact with internal components in the display area DA (see FIG. 1B), thereby reducing a defect rate to provide the display panel DP with improved process reliability. Even when a separate support spacer protruding from the partition wall PW is not provided, the patterning may be possible, thereby miniaturizing the respective surface areas of the emission areas PXA-R, PXA-G and PXA-B. Accordingly, the display panel DP with high resolution may be provided.

Moreover, in the manufacture of the display panel DP having a large area, the manufacture of a mask having a large area may be omitted. Accordingly, process costs may be reduced, and the display panel DP may not be affected by a defect likely to occur in the large area mask, thereby providing the display panel DP with improved process reliability. The content about the plurality of the first emission patterns EP1 may apply to the plurality of the second and third emission patterns EP2 and EP3.

The thin-film encapsulation layer TFE may include lower inorganic encapsulation patterns LIL1, LIL2 and LIL3, an organic encapsulation film OL, and an upper inorganic encapsulation film UIL.

The lower inorganic encapsulation patterns LIL1, LIL2 and LIL3 may include a first lower inorganic encapsulation pattern LIL1 which covers the first light emitting element ED1, a second lower inorganic encapsulation pattern LIL2 which covers the second light emitting element ED2, and a third lower inorganic encapsulation pattern LIL3 which covers the third light emitting element ED3. The first to third lower inorganic encapsulation patterns LIL1, LIL2 and LIL3 may cover the first to third emission opening portions OP1-E, OP2-E and OP3-E, respectively. The first to third lower inorganic encapsulation patterns LIL1, LIL2 and LIL3 may be provided in the form of isolated patterns spaced apart from each other.

Grooves HM1, HM2 and HM3 may be formed in the first to third lower inorganic encapsulation patterns LIL1, LIL2 and LIL3, respectively. For example, the first lower inorganic encapsulation pattern LIL1 may have a first groove HM1 spaced apart from the partition wall PW and the first light emitting element ED1, the second lower inorganic encapsulation pattern LIL2 may have a second groove HM2 spaced apart from the partition wall PW and the second light emitting element ED2, and the third lower inorganic encapsulation pattern LIL3 may have a third groove HM3 spaced apart from the partition wall PW and the third light emitting element ED3.

The organic encapsulation film OL may cover the lower inorganic encapsulation patterns LIL1, LIL2 and LIL3. The upper inorganic encapsulation film UIL may be disposed on the organic encapsulation film OL.

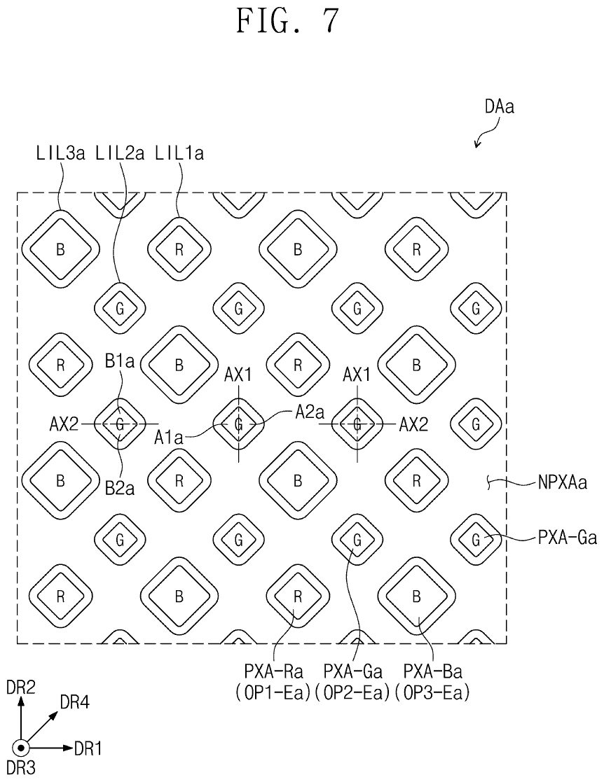

FIG. 7 is an enlarged plan view of a portion of a display area DAa of the display panel DP (see FIG. 2) according to an embodiment of the inventive concept. FIG. 7 illustrates a plan view of the display module DM (see FIG. 1B) when viewed on the display surface IS (see FIG. 1B) of the display module DM (see FIG. 1B).

FIG. 7 illustrates an arrangement of emission areas PXA-Ra, PXA-Ga and PXA-Ba (or emission opening portions OP1-Ea, OP2-Ea and OP3-Ea) having different shapes from those in FIG. 4, and lower inorganic encapsulation patterns LIL1a, LIL2a and LIL3a. Except the shapes, characteristics such as arrangement shapes, surfaces areas, and the like of the emission opening portions OP1-Ea, OP2-Ea and OP3-Ea and the lower inorganic encapsulation patterns LIL1a, LIL2a and LIL3a in FIG. 7 may be substantially the same as those of the emission opening portions OP1-E, OP2-E and OP3-E and the lower inorganic encapsulation patterns LIL1, LIL2 and LIL3 in FIG. 4.

Referring to FIG. 7, the display area DAa may include first to third emission areas PXA-Ra, PXA-Ga and PXA-Ba, and a peripheral area NPXAa which surrounds the first to third emission areas PXA-Ra, PXA-Ga and PXA-Ba. The first to third emission areas PXA-Ra, PXA-Ga and PXA-Ba may be classified according to colors of light emitted toward the outside of the display module DM (see FIG. 2). The first to third emission areas PXA-Ra, PXA-Ga and PXA-Ba may correspond respectively to areas from which light provided from light emitting elements is emitted. The first to third emission areas PXA-Ra, PXA-Ga and PXA-Ba may correspond to first to third emission opening portions OP1-Ea, OP2-Ea and OP3-Ea, respectively. For example, the first emission area PXA-Ra may correspond to the first emission opening portion OP1-Ea, the second emission area PXA-Ga may correspond to the second emission opening portion OP2-Ea, and the third emission area PXA-Ba may correspond to the third emission opening portion OP3-Ea.

At least one of the first to third emission opening portions OP1-Ea, OP2-Ea and OP3-Ea may have a rectangular shape or a rhombic shape in a plan view. At least one of the first to third emission opening portions OP1-Ea, OP2-Ea and OP3-Ea may have four inner side surfaces.

Each of the first to third emission opening portions OP1-Ea, OP2-Ea and OP3-Ea may have a shape symmetrical about at least two axes passing through a center of the emission opening portion. For example, the second emission opening portion OP2-Ea may have a shape symmetrical about a first axis AX1 and a second axis AX2 each passing through the center of the second emission opening portion OP2-Ea. A (1-1)-th area Ala and a (1-2)-th area A2a of the second emission opening portion OP2-Ea, which are divided by the first axis AX1, may be symmetrical with each other. In addition, a (2-1)-th area B1a and a (2-2)-th area B2a of the second emission opening portion OP2-Ea, which are divided by the second axis AX2, may be symmetrical with each other.

In FIG. 7, the embodiment is described with an example of the second emission opening portion OP2-Ea, but the content about the second emission opening portion OP2-Ea may apply to the first and third emission opening portions OP1-Ea and OP3-Ea.

The first to third emission areas PXA-Ra, PXA-Ga and PXA-Ba (or the first to third emission opening portions OP1-Ea, OP2-Ea and OP3-Ea) may have the same shape in a plan view, or alternatively, at least some thereof may have different shapes in a plan view. As an example, FIG. 7 illustrates the first to third emission opening portions OP1-Ea, OP2-Ea and OP3-Ea having the same rectangular shape (rhombic shape) in a plan view.

The first to third lower inorganic encapsulation patterns LIL1a, LIL2a and LIL3a may have various shapes in a plan view. The shapes of the first to third lower inorganic encapsulation patterns LIL1a, LIL2a and LIL3a may correspond to the shapes of the first to third emission opening portions OP1-Ea, OP2-Ea and OP3-Ea, respectively. At least one of the first to third lower inorganic encapsulation patterns LIL1a, LIL2a and LIL3a may have a rectangular shape or a rhombic shape in a plan view.

Each of the first to third lower inorganic encapsulation patterns LIL1a, LIL2a and LIL3a may have a shape symmetrical about at least two axes passing through a center of the each of the first to third lower inorganic encapsulation patterns LIL1a, LIL2a and LIL3a. For example, the second lower inorganic encapsulation pattern LIL2a may have a shape symmetrical about the first axis AX1 and the second axis AX2 each passing through the center of the second lower inorganic encapsulation pattern LIL2a. A (1-1)-th area and a (1-2)-th area of the second lower inorganic encapsulation pattern LIL2a (which correspond respectively to the (1-1)-th area Ala and the (1-2)-th area A2a of the second emission opening portion OP2-Ea), which are divided by the first axis AX1, may be symmetrical with each other. In addition, a (2-1)-th area and a (2-2)-th area of the second lower inorganic encapsulation pattern LIL2a (which correspond respectively to the (2-1)-th area B1a and the (2-2)-th area B2a of the second emission opening portion OP2-Ea), which are divided by the second axis AX2, may be symmetrical with each other.

In FIG. 7, the embodiment is described with an example of the second lower inorganic encapsulation pattern LIL2a, but the content about the second lower inorganic encapsulation pattern LIL2a may apply to the first and third lower inorganic encapsulation patterns LIL1a and LIL3a.

The first to third lower inorganic encapsulation patterns LIL1a, LIL2a and LIL3a may have the same shape in a plan view, or alternatively, at least some thereof may have different shapes in a plan view. As an example, FIG. 7 illustrates the first to third lower inorganic encapsulation patterns LIL1a, LIL2a and LIL3a having the same rectangular shape (or rhombic shape) in a plan view.

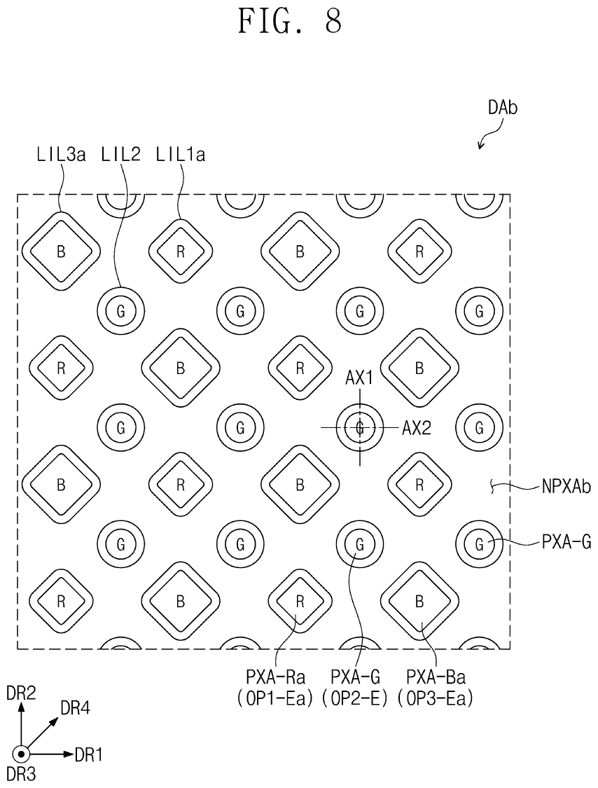

FIG. 8 is an enlarged plan view of a portion of a display area DAb of the display panel DP (see FIG. 2) according to an embodiment of the inventive concept. FIG. 8 illustrates a plan view of the display module DM (see FIG. 1B) when viewed on the display surface IS (see FIG. 1B) of the display module DM (see FIG. 1B).

FIG. 8 illustrates an arrangement of emission areas PXA-Ra, PXA-G and PXA-Ba (or emission opening portions OP1-Ea, OP2-E and OP3-Ea) having different shapes from those in FIG. 4, and lower inorganic encapsulation patterns LIL1a, LIL2 and LIL3a. Except the shapes, characteristics such as arrangement shapes, surfaces areas, and the like of the emission opening portions OP1-Ea, OP2-E and OP3-Ea and the lower inorganic encapsulation patterns LIL1a, LIL2 and LIL3a in FIG. 8 may be substantially the same as those of the emission opening portions OP1-E, OP2-E and OP3-E and the lower inorganic encapsulation patterns LIL1, LIL2 and LIL3 in FIG. 4.

The shapes of the first and third emission opening portions OP1-Ea and OP3-Ea in FIG. 8 may be the same as the shapes of the first and third emission opening portions OP1-Ea and OP3-Ea in FIG. 7, and the shape of the second emission opening portion OP2-E in FIG. 8 may be the same as the shape of the second emission opening portion OP2-E in FIG. 4. That is, in a plan view, some (emission opening portions OP1-Ea and OP3-Ea) of the emission opening portions OP1-Ea, OP2-E and OP3-Ea may have circular shapes, and others (emission opening portion OP2-E) may have rectangular shapes or rhombic shapes. For example, the first and third emission opening portions OP1-Ea and OP3-Ea may have rectangular shapes or rhombic shapes, and the second emission opening portion OP2-E may have a circular shape. Each of the first to third emission opening portions OP1-Ea, OP2-E and OP3-Ea may have a shape symmetrical about at least two axes passing through a center of the emission opening portion.

In addition, shapes of first and third lower inorganic encapsulation patterns LIL1a and LIL3a in FIG. 8 may be the same as the shapes of the first and third lower inorganic encapsulation patterns LIL1a and LIL3a in FIG. 7, and a shape of the second lower inorganic encapsulation pattern LIL2 in FIG. 8 may be the same as the shape of the second lower inorganic encapsulation pattern LIL2 in FIG. 4. That is, in a plan view, some (lower inorganic encapsulation patterns LIL1a and LIL3a) of the lower inorganic encapsulation patterns LIL1a, LIL2 and LIL3a may have rectangular shapes or rhombic shapes, and others (lower inorganic encapsulation pattern LIL2) may have circular shapes. For example, the first and third lower inorganic encapsulation patterns LIL1a and LIL3a may have rectangular shapes or rhombic shapes, and the second lower inorganic encapsulation pattern LIL2 may have a circular shape. Each of the first to third lower inorganic encapsulation patterns LIL1a, LIL2 and LIL3a may have a shape symmetrical about at least two axes passing through a center of the lower inorganic encapsulation pattern.

Referring to FIGS. 4 to 8, each of the emission opening portions OP1-E, OP2-E and OP3-E according to an embodiment of the inventive concept may have a shape symmetrical about at least two axes, and so as to corresponding thereto, each of the lower inorganic encapsulation patterns LIL1, LIL2 and LIL3 may have a shape symmetrical about the at least two axes. As the lower inorganic encapsulation patterns LIL1, LIL2 and LIL3 have the symmetrical shapes, stress may not be concentrated on a certain position on the lower inorganic encapsulation patterns LIL1, LIL2 and LIL3, and the lower inorganic encapsulation patterns LIL1, LIL2 and LIL3 may be more robust. Thus, foreign substances introduced through an separation area between the partition wall PW and each of the lower inorganic encapsulation patterns LIL1, LIL2 and LIL3 in a cross-sectional view, and foreign substances introduced into the grooves HM1 HM2 and HM3 of the lower inorganic encapsulation patterns LIL1, LIL2 and LIL3 may be reduced or removed, and pixel defects (dark dot, pixel shrinkage, and the like) of the display panel DP, which are generated due to the foreign substances, may be reduced or removed.

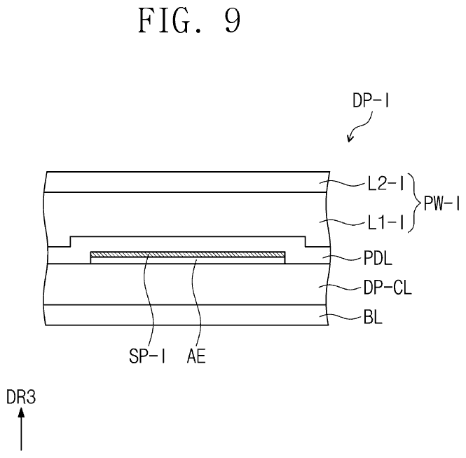

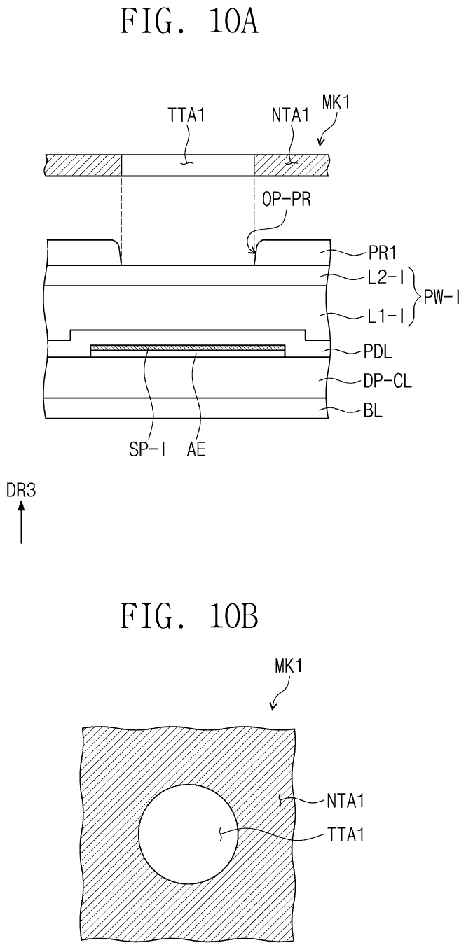

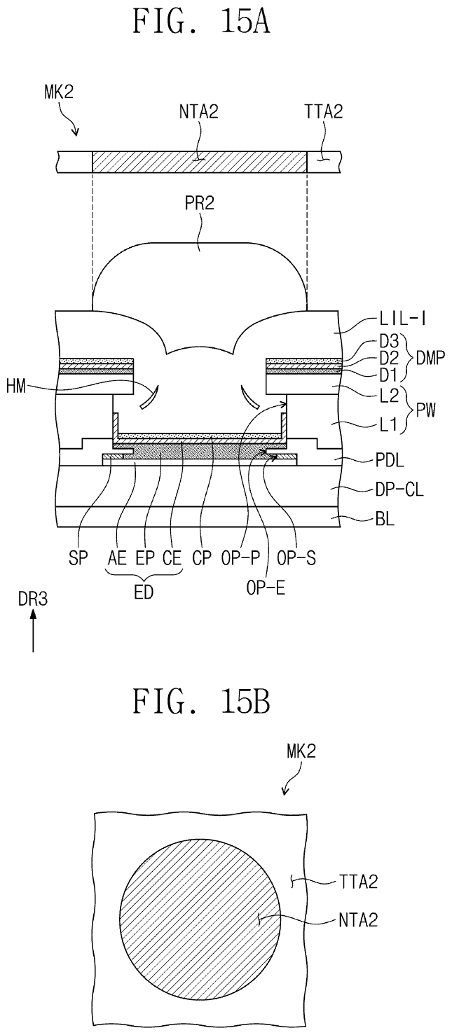

FIGS. 9, 10A, 11 to 14, 15A, 16, and 17 are cross-sectional views illustrating some of steps of a method for manufacturing a display panel according to an embodiment of the inventive concept. FIGS. 10B and 15B are plan views of masks MK1 and MK2 according to an embodiment of the inventive concept. Embodiments will be described with reference to FIGS. 9 to 17 by denoting the same/similar components as/to those described with reference to FIGS. 1 to 6 as the same/similar reference numbers or symbols, and avoiding redundant explanation.

The method for manufacturing the display panel according to an embodiment of the inventive concept may include providing a preliminary display panel including a base layer, a pixel defining film disposed on the base layer, and a preliminary partition wall disposed on the pixel defining film, patterning a first photoresist layer by using a first mask to form a first photoresist pattern, the first mask including a first transmission part and a first light blocking part which surrounds the first transmission part in a plan view, etching the preliminary partition wall by using the first photoresist pattern to form a partition wall having an undercut shape in which a partition wall opening portion is defined, etching the pixel defining film by using the first photoresist pattern to form, in the pixel defining film, an emission opening portion corresponding to a shape of the first transmission part, and forming a light emitting element in the emission opening portion and the partition wall opening portion, the light emitting element including an anode, an emission pattern, and a cathode. The first transmission part may have a shape symmetrical about at least two axes passing through a center of the first transmission part.

Hereinafter, a method for forming one light emitting element ED, and a lower inorganic encapsulation pattern LIL, an organic encapsulation film OL, and an upper inorganic encapsulation film UIL, which cover the light emitting element ED, will be described with reference to FIGS. 9 to 17. A display panel DP formed through the method described with reference to FIGS. 9 to 17 may correspond to the display panel DP in FIG. 5.

Referring to FIG. 9, the method for manufacturing the display panel according to an embodiment of the inventive concept may include providing a preliminary display panel DP-I. The preliminary display panel DP-I provided in this embodiment may include a base layer BL, a circuit element layer DP-CL, an anode AE, a sacrificial layer SP-I, a pixel defining film PDL, and a preliminary partition wall PW-I. The preliminary display panel DP-I may include a first preliminary partition wall layer L1-I and a second preliminary partition wall layer L2-I.

The circuit element layer DP-CL may be formed through a typical process for manufacturing a circuit element by forming an insulating layer, a semiconductor layer, and a conductive layer through a method such as coating or deposition, and then selectively patterning the insulating layer, the semiconductor layer, and the conductive layer through a photolithography process and an etching process to form a semiconductor pattern, a conductive pattern, signal lines, and the like.

A preliminary anode layer and a preliminary sacrificial layer may be formed on the circuit element layer DP-CL. The anode AE and the sacrificial layer SP-I may be formed through the same patterning process using a same mask. The pixel defining film PDL may be formed on the base layer BL. The pixel defining film PDL may cover both the anode AE and the sacrificial layer SP-I.

The first preliminary partition wall layer L1-I may be formed on the pixel defining film PDL, and the second preliminary partition wall layer L2-I may be formed on the first preliminary partition wall layer L1-I. The first preliminary partition wall layer L1-I and the second preliminary partition wall layer L2-I may be formed through a conductive material deposition process. In an embodiment of the inventive concept, the first preliminary partition wall layer L1-I may include aluminum (Al), and the second preliminary partition wall layer L2-I may include titanium (Ti). However, the materials of the first preliminary partition wall layer L1-I and the second preliminary partition wall layer L2-I are not limited thereto. For example, the first preliminary partition wall layer L1-I and the second preliminary partition wall layer L2-I may each include a metal, a transparent conductive oxide (TCO), or a combination thereof. The metal may include gold (Au), silver (Ag), aluminum (Al), magnesium (Mg), lithium (Li), molybdenum (Mo), titanium (Ti), copper (Cu), or an alloy. The transparent conductive oxide may include an indium tin oxide (ITO), an indium zinc oxide (IZO), a zinc oxide, an indium oxide, an indium gallium oxide, an indium gallium zinc oxide (IGZO), or an aluminum zinc oxide.

Thereafter, referring to FIGS. 10A and 10B, the method for manufacturing the display panel according to an embodiment of the inventive concept may include forming a first photoresist pattern PR1 on the preliminary partition wall PW-I. The first photoresist pattern PR1 may be formed by forming the first photoresist layer on the preliminary partition wall PW-I (see FIG. 9) and then patterning the first photoresist layer by using a first mask MK1. The first mask MK1 may include a first transmission part TTA1 and a first light blocking part NTA1 that surrounds the first transmission part TTA1. The first transmission part TTA1 of the first mask MK1 may have a shape symmetrical about at least two axes passing through a center of the first transmission part TTA1 in a plan view. As an example, FIG. 10B illustrates the first transmission part TTA1 having a circular shape, but an embodiment of the inventive concept is not limited thereto. For example, the first transmission part TTA1 may have a rectangular shape or a rhombic shape.

A photo resist opening portion OP-PR may be defined in the first photoresist pattern PR1 through a patterning process. The photo resist opening portion OP-PR may be disposed in an area corresponding to the anode AE. The photo resist opening portion OP-PR may correspond to the shape of the first transmission part TTA1. That is, the photo resist opening portion OP-PR may have a circular shape, a rectangular shape, or a rhombic shape in a plan view.

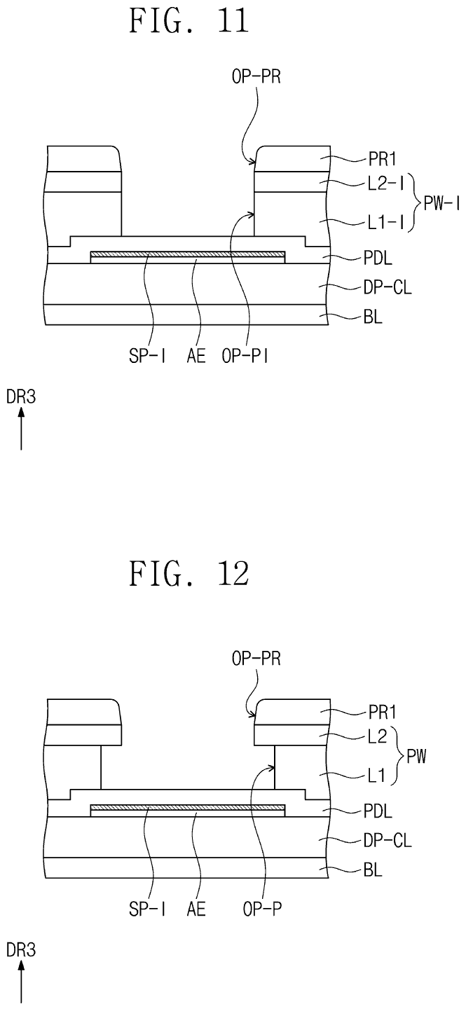

Thereafter, referring to FIGS. 11 and 12, the method for manufacturing the display panel according to an embodiment of the inventive concept may include etching the preliminary partition wall PW-I to form a partition wall PW having an undercut shape in which a partition wall opening portion OP-P is defined. The forming of the partition wall PW may include primary etching of the first preliminary partition wall layer L1-I and the second preliminary partition wall layer L2-I, and secondary etching of the first preliminary partition wall layer L1-I.

Referring to FIG. 11, in the primary etching of the first preliminary partition wall layer L1-I and the second preliminary partition wall layer L2-I, the first preliminary partition wall layer L1-I and the second preliminary partition wall layer L2-I may be anisotropic dry-etched by using the first photoresist pattern PR1 as a mask. A portion which is not covered by the first photoresist pattern PR1 of the preliminary partition wall PW-I may be etched and removed. For example, a preliminary partition wall opening portion OP-PI may be formed in an area not covered by the first photoresist pattern PR1.

The anisotropic primary dry etching process in this embodiment may be performed in an etching environment in which an etch rate of the first preliminary partition wall layer L1-I and the second preliminary partition wall layer L2-I are substantially the same. Accordingly, an inner side surface of the first preliminary partition wall layer L1-I and an inner side surface of the second preliminary partition wall layer L2-I, which define the preliminary partition wall opening portion OP-PI, may be substantially aligned with each other.

Thereafter, as illustrated in FIG. 12, in the secondary etching of the first preliminary partition wall layer L1-I (see FIG. 11), the first preliminary partition wall layer L1-I may be wet-etched by using the first photoresist pattern PR1 as a mask. Accordingly, a portion of the first preliminary partition wall layer L1-I may be etched to form the partition wall opening portion OP-P. The partition wall opening portion OP-P may be formed in an area corresponding to a part of the anode AE.

The secondary wet etching process in an embodiment of the inventive concept may be performed in an etching environment in which etch selectivity between the first preliminary partition wall layer L1-I and the second preliminary partition wall layer L2-I (see FIG. 11) is great. Accordingly, the inner side surface of the partition wall PW, which defines the partition wall opening portion OP-P, may have an undercut shape in a cross-sectional view. Specifically, as the first preliminary partition wall layer L1-I has a higher etch rate for an etchant than an etch rate of the second preliminary partition wall layer L2-I, the first preliminary partition wall layer L1-I may be mainly etched. Accordingly, a first inner side surface of a first partition wall layer L1 may be formed to be recessed inward from a second inner side surface of a second partition wall layer L2. Due to a difference in etch rates between the first preliminary partition wall layer L1-I and the second preliminary partition wall layer L2-I, a tip part may be formed on the partition wall PW.

As an example, FIGS. 11 and 12 illustrate the forming of one partition wall opening portion OP-P corresponding to one emission area. In an embodiment, forming the first partition wall opening portion OP1-P (see FIG. 6) corresponding to the first emission area PXA-R (see FIG. 6) and forming the first light emitting element ED1 (see FIG. 6) may be performed, and then forming the second partition wall opening portion OP2-P (see FIG. 6) corresponding to the second emission area PXA-G (see FIG. 6) and forming the second light emitting element ED2 (see FIG. 6) may be performed. Thereafter, forming the third partition wall opening portion OP3-P (see FIG. 6) corresponding to the third emission area PXA-B (see FIG. 6) and firming the third light emitting element ED3 (see FIG. 6) may be performed. Alternatively, in an embodiment, the first to third partition wall opening portions OP1-P, OP2-P and OP3-P corresponding to the first to third emission area PXA-R, PXA-G and PXA-B, respectively, may be formed at the same time, and then the first to third light emitting elements ED1, ED2 and ED3 may be formed.

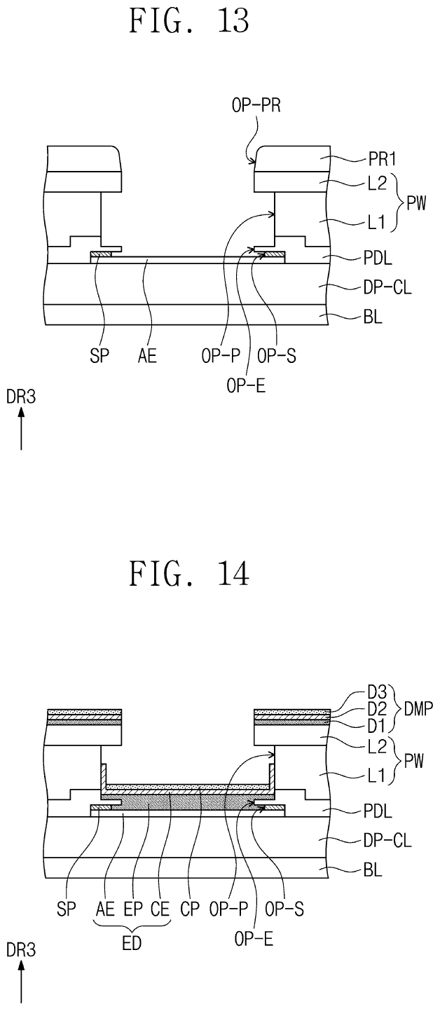

Thereafter, referring to FIG. 13, the method for manufacturing the display panel according to an embodiment of the inventive concept may include etching the pixel defining film PDL by using the first photoresist pattern PR1 to form an emission opening portion OP-E in the pixel defining film PDL.

In the etching of the pixel defining film PDL, the pixel defining film PDL may be dry-etched using the first photoresist pattern PR1 and the partition wall PW (e.g., the second partition wall layer L2) as a mask. A portion of the pixel defining film PDL which is not covered by the first photoresist pattern PR1 and the partition wall PW may be etched and removed. As a result, the emission opening portion OP-E surrounded by an edge of the partition wall opening portion OP-P in a plan view may be formed in the pixel defining film PDL.

As the first photoresist pattern PR1 is patterned using the first mask MK1 (see FIG. 10A), and the pixel defining film PDL is etched using the first photoresist pattern PR1, the emission opening portion OP-E defined in the pixel defining film PDL may correspond to the shape of the first transmission part TTA1 (see FIG. 10A). That is, the forming of the emission opening portion OP-E in the pixel defining film PDL may include forming the emission opening portion OP-E having a circular shape, a rectangular shape, or a rhombic shape in a plan view.

In addition, the method for manufacturing the display panel according to an embodiment of the inventive concept may include etching the sacrificial layer SP-I (see FIG. 12) to form a sacrificial pattern SP having a sacrificial opening portion OP-S in an area corresponding to the emission opening portion OP-E.

In the etching of the sacrificial layer SP-I, the sacrificial layer SP-I may be wet-etched using the first photoresist pattern PR1 and the partition wall PW (e.g., the second partition wall layer L2) as a mask. A portion of the sacrificial layer SP-I which is not covered by the first photoresist pattern PR1 and the partition wall PW may be etched and removed. As a result, the sacrificial pattern SP may be formed from the sacrificial layer SP-I. The sacrificial opening portion OP-S disposed in an area corresponding to the emission opening portion OP-E may be defined in the sacrificial pattern SP.

In the etching of the sacrificial layer SP-I, the sacrificial layer SP-I may be anisotropic dry-etched using the first photoresist pattern PR1 and the partition wall PW (e.g., the second partition wall layer L2) as a mask. In this case, an undercut portion in the sacrificial layer SP-I may not be formed.

The etching of the sacrificial pattern SP may be performed in an etching environment in which etch selectivity between the sacrificial pattern SP and the anode AE is great, and accordingly, the anode AE may be prevented from being etched when etching the sacrificial pattern SP. That is, the sacrificial pattern SP having a higher etch rate than the anode AE may be disposed between the pixel defining film PDL and the anode AE, thereby preventing the anode AE from being etched together and damaged during the etching of the sacrificial pattern SP.

Thereafter, referring to FIG. 14, the method for manufacturing the display panel according to an embodiment of the inventive concept may include removing the first photoresist pattern PR1 (see FIG. 13) and forming a light emitting element ED in the emission opening portion OP-E and the partition wall opening portion OP-P, the light emitting element ED including the anode AE, an emission pattern EP, and a cathode CE.

The forming of the light emitting element ED may include forming the emission pattern EP and forming the cathode CE. In addition, the forming of the light emitting element ED may include forming a dummy layer DMP including the same material as each of the emission pattern EP and the cathode CE on the partition wall PW.

The forming of the emission pattern EP may include a deposition process of a light emitting layer. For example, the forming of the emission pattern EP may include thermally evaporating the light emitting layer. The light emitting layer may be separated due to the tip part formed on the partition wall PW and the separated light emitting layers may be deposited inside the partition wall opening portion OP-P and on the partition wall PW. The light emitting layer formed in the partition wall opening portion OP-P may form the emission pattern EP, and the light emitting layer formed on the partition wall PW may form a first dummy layer D1. That is, the emission pattern EP may be formed on the anode AE so as to overlap the partition wall opening portion OP-P, and the emission pattern EP may be formed while covering the anode AE and the pixel defining film PDL.

The first dummy layer D1 formed together in the forming of the emission pattern EP may include an organic material. For example, the first dummy layer D1 may include the same material as the emission pattern EP. The first dummy layer D1 may be formed together with the emission pattern EP at the same time through one process and be separated from the emission pattern EP due to the undercut shape of the partition wall PW.

The forming of the cathode CE may include a deposition process of a cathode layer. For example, the forming of the cathode CE may include sputtering the cathode layer. The cathode layer may be separated due to the tip part formed on the partition wall PW and the separated cathode layers may be deposited inside the partition wall opening portion OP-P and on the partition wall PW. The cathode layer formed in the partition wall opening portion OP-P may form the cathode CE, and the cathode layer formed on the partition wall PW may form a second dummy layer D2. That is, the cathode CE may be formed on the emission pattern EP in an area corresponding to the partition wall opening portion OP-P and the cathode CE may be formed while covering the emission pattern EP. In addition, the cathode CE may come into contact with the inner side surface of the first partition wall layer L1 and be formed to extend along the inner side surface of the first partition wall layer L1.

The second dummy layer D2 formed together in the forming of the cathode CE may include a conductive material. For example, the second dummy layer D2 may include the same material as the cathode CE. The second dummy layer D2 may be formed together with the cathode CE at the same time through one process and be separated from the cathode CE due to the undercut shape of the partition wall PW.

The anode AE, the emission pattern EP, and the cathode CE may be stacked in sequence in the third direction DR3. The anode AE, the emission pattern EP, and the cathode CE may form the light emitting element ED.

In an embodiment, the method for manufacturing the display panel according to an embodiment of the inventive concept may further include forming a capping pattern CP. The forming of the capping pattern CP may include a deposition process of a capping pattern layer. The capping pattern layer may be separated due to the tip part formed on the partition wall PW and the separated capping pattern layers may be deposited inside the partition wall opening portion OP-P and on the partition wall PW. The capping pattern layer formed in the partition wall opening portion OP-P may form the capping pattern CP and the capping pattern layer formed on the partition wall PW may form a third dummy layer D3.

The third dummy layer D3 formed together in the forming of the capping pattern CP may include a conductive material. For example, the third dummy layer D3 may include the same material as the capping pattern CP. The third dummy layer D3 may be formed together with the capping pattern CP at the same time through one process and be separated from the capping pattern CP due to the undercut shape of the partition wall PW. In an embodiment of the inventive concept, the processes of forming the capping pattern CP and the third dummy layer D3 may be omitted.

The first dummy layer D1, the second dummy layer D2, and the third dummy layer D3 may be stacked in sequence in the third direction DR3. The first dummy layer D1, the second dummy layer D2, and the third dummy layer D3 may form the dummy layer DMP.

Referring to FIGS. 15A and 15B, the method for manufacturing the display panel according to an embodiment of the inventive concept may include depositing a lower inorganic encapsulation layer LIL-I that covers the partition wall PW and the light emitting element ED.

The lower inorganic encapsulation layer LIL-I may be formed through a chemical vapor deposition (CVD) process. The lower inorganic encapsulation layer LIL-I may be formed so as to cover the cathode CE (or the capping pattern CP) and the partition wall PW. A portion of the lower inorganic encapsulation layer LIL-I may fill the partition wall opening portion OP-P. The lower inorganic encapsulation layer LIL-I may have a groove HM where the lower inorganic encapsulation pattern LIL is absent due to bad step coverage of the lower inorganic encapsulation layer LIL-I. The groove HM may be formed when the lower inorganic encapsulation layer LIL-I is formed to fill the partition wall opening portion OP-P. The groove HM may be spaced apart from the partition wall PW and the light emitting element ED.

Thereafter, the method for manufacturing the display panel according to an embodiment of the inventive concept may include forming a second photoresist pattern PR2 on the lower inorganic encapsulation layer LIL-I. The second photoresist pattern PR2 may be formed by forming a second photoresist layer on the lower inorganic encapsulation layer LIL-I and then patterning the second photoresist layer by using a second mask MK2. The second mask MK2 may include a second light blocking part NTA2 and a second transmission part NTA2 that surrounds the second light blocking part NTA2. The second light blocking part NTA2 of the second mask MK2 may have a shape symmetrical about at least two axes passing through a center of the second light blocking part NTA2. As an example, FIG. 15B illustrates the second light blocking part NTA2 having a circular shape, but an embodiment of the inventive concept is not limited thereto. For example, the second light blocking part NTA2 may have a rectangular shape or a rhombic shape.

The second photoresist pattern PR2 may be formed in the form of a pattern corresponding to the light emitting element ED through a patterning process. The second photoresist pattern PR2 may correspond to a shape of the second light blocking part NTA2. That is, the second photoresist pattern PR2 may have a circular shape, a rectangular shape, a rhombic shape, or the like.

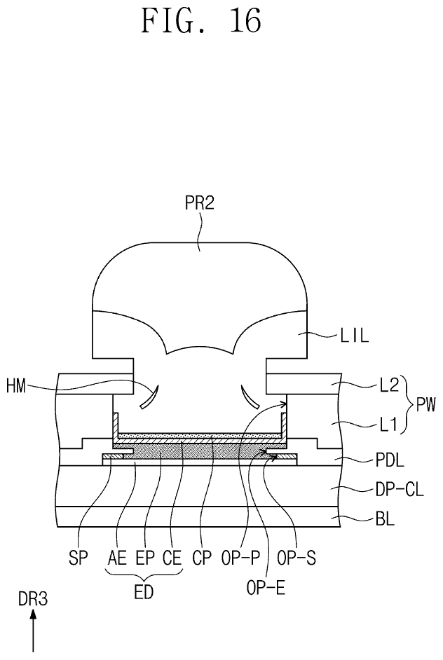

Referring to FIG. 16, the method for manufacturing the display panel according to an embodiment of the inventive concept may include etching the lower inorganic encapsulation layer LIL-I (FIG. 15A) to form a lower inorganic encapsulation pattern LIL. The lower inorganic encapsulation layer LIL-I may be dry-etched using the second photoresist pattern PR2 as a mask. A portion of the lower inorganic encapsulation layer LIL-I which is not covered by the second photoresist pattern PR2 may be removed and a portion of the lower inorganic encapsulation layer LIL-I which remains without being etched may become the lower inorganic encapsulation pattern LIL.

As the second photoresist pattern PR2 is patterned using the second mask MK, and the lower inorganic encapsulation layer LIL-I is etched using the second photoresist pattern PR2 as a mask, the lower inorganic encapsulation pattern LIL may correspond to the shape of the second light blocking part NTA2. That is, the etching of the lower inorganic encapsulation layer LIL-I to form the lower inorganic encapsulation pattern LIL may include forming the lower inorganic encapsulation pattern LIL having a circular shape, a rectangular shape, or a rhombic shape in a plan view.

Thereafter, the method for manufacturing the display panel according to an embodiment of the inventive concept may include removing the dummy layer DMP (FIG. 15A). The second and third dummy layers D2 and D3 of the dummy layers D1, D2 and D3 may be removed through wet etching, and the first dummy layer D1 of the dummy layers D1, D2 and D3 may be removed through a stripper.

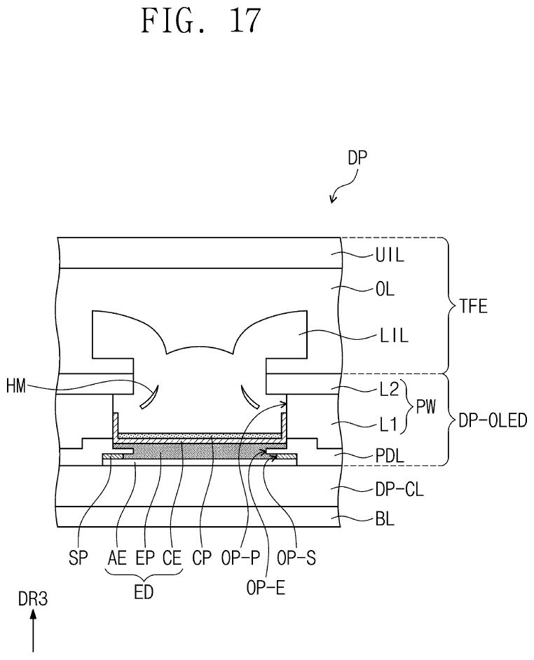

Thereafter, referring to FIG. 17, the method for manufacturing the display panel according to an embodiment of the inventive concept may include removing the second photoresist pattern PR2 (FIG. 16) and forming the organic encapsulation film OL that covers the lower inorganic encapsulation pattern LIL. The organic encapsulation film OL may be formed by applying an organic material through an inkjet process, but the process forming the organic encapsulation film OL is not limited thereto. The organic encapsulation film OL may provide a planarized top surface.

In addition, the method for manufacturing the display panel according to an embodiment of the inventive concept may include forming an upper inorganic encapsulation film UIL to complete the display panel DP. An inorganic material may be deposited to form the upper inorganic encapsulation film UIL. Accordingly, the display panel DP including the base layer BL, the circuit element layer DP-CL, a display element layer DP-OLED, and a thin-film encapsulation layer TFE may be formed.

As described above, each of the emission opening portions according to the embodiment of the inventive concept may have the shape symmetrical about the at least two axes, and so as to corresponding thereto, each of the lower inorganic encapsulation patterns may have the shape symmetrical about the at least two axes. As the lower inorganic encapsulation patterns have the symmetrical shapes, the stress may not be concentrated on the certain position on each of the lower inorganic encapsulation patterns, and the lower inorganic encapsulation patterns may be more robust. Thus, the foreign substances introduced through the separation area between the partition wall and each of the lower inorganic encapsulation patterns on a cross-section, and the foreign substances introduced into the grooves of the lower inorganic encapsulation patterns may be reduced or removed, and the pixel defects (dark dot, pixel shrinkage, and the like) of the display panel, which are generated due to the foreign substances, may be reduced or removed.

Although the embodiments of the present inventive concept have been described, it is understood that the present inventive concept should not be limited to these embodiments but various changes and modifications can be made by one ordinary skilled in the art within the spirit and scope of the present inventive concept as hereinafter claimed. Therefore, the technical scope of the inventive concept is not limited to the contents described in the detailed description of the specification, but should be determined by the claims.

What is claimed is:

1. A display panel comprising:
a base layer;
a pixel defining film disposed on the base layer and having an emission opening portion;
a partition wall disposed on the pixel defining film and having a partition wall opening portion disposed in an area corresponding to the emission opening portion;
a light emitting element comprising an anode, an emission pattern, and a cathode in contact with the partition wall, and disposed in the emission opening portion and the partition wall opening portion; and
a lower inorganic encapsulation pattern having a groove spaced apart from the partition wall and the light emitting element, and configured to cover the light emitting element,
wherein the emission opening portion has a shape symmetrical about at least two axes passing through a center of the emission opening portion in a plan view.

2. The display panel of claim 1, wherein the light emitting element comprises a first light emitting element, a second light emitting element, and a third light emitting element which emit light having different colors from each other, and
wherein the emission opening portion comprises a first emission opening portion disposed in an area corresponding to the first light emitting element, a second emission opening portion disposed in an area corresponding to the second light emitting element, and a third emission opening portion disposed in an area corresponding to the third light emitting element.

3. The display panel of claim 2, wherein at least one of the first to third emission opening portions has a circular shape in a plan view.

4. The display panel of claim 2, wherein at least one of the first to third emission opening portions is symmetrical about all axes passing through a center of the at least one emission opening portion in a plan view.

5. The display panel of claim 2, wherein each of the first to third emission opening portions has a circular shape in a plan view.

6. The display panel of claim 2, wherein at least one of the first to third emission opening portions has a rectangular shape or a rhombic shape in a plan view.

7. The display panel of claim 2, wherein at least one of the first to third emission opening portions has four inner side surfaces.

8. The display panel of claim 2, wherein each of the first to third emission opening portions has a rectangular shape or a rhombic shape in a plan view.

9. The display panel of claim 2, wherein an end of the lower inorganic encapsulation pattern surrounds an edge of the emission opening portion in a plan view.

10. The display panel of claim 2, wherein the lower inorganic encapsulation pattern has a shape symmetrical about at least two axes passing through a center of the lower inorganic encapsulation pattern in a plan view.

11. The display panel of claim 2, wherein the lower inorganic encapsulation pattern comprises:
a first lower inorganic encapsulation pattern configured to cover the first light emitting element and having a first groove spaced apart from the partition wall and the first light emitting element;
a second lower inorganic encapsulation pattern configured to cover the second light emitting element and having a second groove spaced apart from the partition wall and the second light emitting element; and
a third lower inorganic encapsulation pattern configured to cover the third light emitting element and having a third groove spaced apart from the partition wall and the third light emitting element.

12. The display panel of claim 11, wherein at least one of the first to third lower inorganic encapsulation patterns is symmetrical about all axes passing through a center of the at least one lower inorganic encapsulation pattern in a plan view.

13. The display panel of claim 11, wherein each of the first to third lower inorganic encapsulation patterns has a circular shape in a plan view.

14. The display panel of claim 11, wherein at least one of the first to third lower inorganic encapsulation patterns has a rectangular shape or a rhombic shape in a plan view.

15. The display panel of claim 11, wherein each of the first to third lower inorganic encapsulation patterns has a rectangular shape or a rhombic shape in a plan view.

16. A method for manufacturing a display panel, the method comprising:
providing a preliminary display panel comprising a base layer, a pixel defining film disposed on the base layer, and a preliminary partition wall disposed on the pixel defining film;
patterning a first photoresist layer by using a first mask to form a first photoresist pattern, the first mask comprising a first transmission part and a first light blocking part which surrounds the first transmission part in a plan view;
etching the preliminary partition wall to form a partition wall having an undercut using the first photoresist pattern as a mask;
etching the pixel defining film to form an emission opening portion corresponding to a shape of the first transmission part using the first photoresist pattern as a mask; and
forming a light emitting element in the emission opening portion and the partition wall opening portion, the light emitting element comprising an anode, an emission pattern, and a cathode,
wherein the first transmission part has a shape symmetrical about at least two axes passing through a center of the first transmission part.

17. The method of claim 16, further comprising:
depositing a lower inorganic encapsulation layer which covers the partition wall and the light emitting element;
patterning a second photoresist layer by using a second mask to form a second photoresist pattern, the second mask comprising a second light blocking part and a second transmission part which surrounds the second light blocking part in a plan view; and
etching the lower inorganic encapsulation layer by using the second photoresist pattern to form a lower inorganic encapsulation pattern in an area corresponding to the second light blocking part,
wherein the second light blocking part has a shape symmetrical about at least two axes passing through a center of the second light blocking part.

18. The method of claim 17, wherein the depositing of the lower inorganic encapsulation layer which covers the partition wall and the light emitting element comprises forming a groove spaced apart from the partition wall and the light emitting element.

19. The method of claim 17, wherein the etching of the lower inorganic encapsulation layer to form the lower inorganic encapsulation pattern comprises forming the lower inorganic encapsulation pattern having a circular shape, a rectangular shape, or a rhombic shape in a plan view, and the forming of the emission opening portion in the pixel defining film comprises forming the emission opening portion having a circular shape, a rectangular shape, or a rhombic shape in a plan view.

20. An electronic device providing an image, the electronic device comprising:
a window;
a display panel disposed below the window; and
a housing disposed below the display panel and coupled with the window to accommodate the display panel,
wherein the display panel comprising:
a base layer;
a pixel defining film disposed on the base layer and having an emission opening portion;
a partition wall disposed on the pixel defining film and having a partition wall opening portion in an area corresponding to the emission opening portion;
a light emitting element comprising an anode, an emission pattern, and a cathode in contact with the partition wall, and disposed in the emission opening portion and the partition wall opening portion; and
a lower inorganic encapsulation pattern having a groove spaced apart from the partition wall and the light emitting element, and configured to cover the light emitting element, and
wherein the emission opening portion has a shape symmetrical about at least two axes passing through a center of the emission opening portion in a plan view.
